(19) United States
(12) Patent Application Publication
(10) Pub. No.: US 2007/0138501 A1
(43) Pub. Date: Jun. 21, 2007

(54) Semiconductor device and method of manufacturing semiconductor device

(75) Inventors: Taro Sugizaki, Kanagawa (JP); Motoaki Nakamura, Kanagawa (JP); Motonari Honda, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/636,656

(22) Filed: Dec. 11, 2006

(30) Foreign Application Priority Data
Dec. 15, 2005 (JP) 2005-361212
Oct. 19, 2006 (JP) 2005-284551

(51) Int. Cl. H01L 29/74

(52) U.S. Cl. 257/107

(57) ABSTRACT

A semiconductor device has a thyristor including a first region of a first conduction type, a second region of a second conduction type opposite to the first conduction type, a third region of the first conduction type, and a fourth region of the second conduction type, in sequential junction, and has a gate electrode at the third region, wherein the second region is formed in a semiconductor substrate, and the first region is formed over the second region. A part of the region of a thyristor is thus provided with a laminate structure, whereby a reduction in element area can be achieved, and an enhanced punch-through resistance can be attained.

### CROSS REFERENCES TO RELATED APPLICATIONS

The present invention contains subject matter related to Japanese Patent Application JP 2006-284551, filed in the Japanese Patent Office on Oct. 19, 2006, and Japanese Patent Application JP 2005-361212, filed in the Japanese Patent Office on Dec. 15, 2005, the entire contents of which being incorporated herein by reference.

### BACKGROUND OF THE INVENTION

1. Field of the Invention

The present invention relates to a semiconductor device having a thyristor configuration and a method of manufacturing the semiconductor device, wherein scaling in the lateral directions is secured and process margins are secured.

2. Description of the Related Art

Manufacture of 90 nm generations of SRAMs has been started in the later part of the year 2004. However, an SRAM crisis has been vigorously pointed out in that, in the development of the coming 65 nm generation of SRAMs, extreme difficulties are encountered in circuit designing because there are conspicuous problems of the rise in leakage current and the reduction in operation margin.

Enhancement of the performance of semiconductor devices has hitherto been achieved by miniaturization of transistors according to the scaling rule. In recent years, however, the off-leak of transistors has increased at each transition from an older generation to a newer generation due to the physical limit of miniaturization, processing dispersions, fluctuations in impurity distribution and, further, the performance scaling with a fixed current driving capability.

While the SRAM has been widely used as a mixed mounting type memory, the increase in leakage current at stand-by time and the reduction in operation margin which arise from this problem have come to be conspicuous. Particularly from the 65 nm generation on, it will be demanded to lower the leakage from the memory cell itself, which is the fundamental cause of these problems. In consideration of such circumstances, the necessity of a substituent memory comparable in performance to an SRAM can be understood. Objective factors in the development of a memory as a substitute for the mixed mounting type SRAM include [a] a high operating speed comparable to that of an SRAM, [b] a low stand-by current, [c] ease of scaling, and [d] affinity for CMOS logic processes. In view of this, there has been proposed a TRAM (Thyristor Random Access Memory) in which a thyristor is used, the turn-on and turn-off characteristics of the thyristor are controlled by a gate electrode realized on the thyristor, and which is connected in series with an access transistor. This memory is designed to perform memory actions with the off region of the thyristor as “0”, and the on region as “1”.

A thyristor has a basic structure in which a p-type region p1, an n-type region n1, a p-type region p2 and an n-type region n2 are formed in sequential junction; for example, n-type silicon and p-type silicon are formed in four layers. Hereinafter, this basic structure will be referred to as p1/n1/p2/n2 structure. Two kinds of configurations have been proposed by T-RAM. One of the two configurations is a configuration in which the p1/n1/p2/n2 structure is vertically formed on a silicon substrate. The other is a configuration in which the p1/n1/p2/n2 structure is horizontally formed in a silicon layer by use of an SOI substrate. In either configuration, a gate electrode having a MOS structure is provided at p2 of the p1/n1/p2/n2 structure (refer to, for example, Patent Document 1 and Non-patent Documents 1 to 3).

For example, as shown in FIG. 40A, a semiconductor device with a thyristor configuration is sequentially provided with a p-type region p1, an n-type region n1, a p-type region p2 and an n-type region n2 in four layers to form the p1/n1/p2/n2 structure. In addition, an anode A is connected to the p-type region p1 provided on one end side, while a cathode K is connected to the n-type region n2 provided on the other end side. Further, a gate electrode G is arranged at the n-type region n1 disposed on the inner side.

In the semiconductor device with the thyristor configuration as just-mentioned, as shown in FIG. 40B, when a forward bias is impressed between the anode A and the cathode K, holes are supplied from the p-type region p1 in connection with the anode A into the n-type region n1, whereas electrons are supplied from the n-type region n2 in connection with the cathode K into the p-type region p2. The holes and the electrons are recombined at a junction part between the n-type region n1 and the p-type region p2, whereby a current is made to flow, resulting in an ON state.

Besides, as shown in FIG. 40C, an OFF state is obtained by impressing a backward bias between the anode A and the cathode K, but, in this case, it takes a time on the order of several milliseconds until a substantial OFF state is obtained. To be more specific, once the ON state is obtained, the OFF state would not be spontaneously attained by only applying a backward bias between the anode A and the cathode K. The OFF state can be obtained by putting the current to below the holding current or turning off the power supply so as to cause the excess of carriers flowing in the n-type region n1 and the p-type region p2 to be completely swept away from these regions or recombined.

Therefore, in the case of effecting the switching from the ON state to the OFF state, a backward voltage is impressed between the anode A and the cathode K and, simultaneously, a voltage is impressed on the gate electrode provided at the p-type region p2. This generates an electric field in the p-type region p2, whereby the electrons as the excess of carriers are forcibly discharged, and a substantial OFF state is obtained more swiftly.

In the next place, the relationship between the voltage (V_{AK}) between the anode A and the cathode K in the semiconductor device of the thyristor configuration as above-mentioned and the current (I) flowing in the semiconductor device will be described, referring to FIG. 41.

As shown in FIG. 41, as a positive voltage is impressed on the anode A, the pn junction between the n-type region n1 and the p-type region p2 is put into a forward bias condition when the voltage V_{AK} reaches a critical voltage V_{FB}, whereby the voltage V_{AK} is lowered, and a current of not less than the holding current I_{H} begins to flow. It is to be noted here that, before the voltage V_{AK} reaches the critical voltage V_{FB}, only a switching current I_{S} less than the holding current I_{H} flows, and a current more than the holding current I_{H} begins to flow when the voltage V_{AK} has exceeded the critical voltage V_{FB}.

In addition, as shown in FIG. 42, when it is intended to produce a thyristor 311 of the same planar type as that of a MOSFET on a bulk-Si wafer, it may be necessary to perform isolation in the vertical direction by the second p-type region p2 and to form the first p-type region p1 and the first n-type region n1 as a double diffusion layer, since it is impossible to achieve BOX (Buried Oxide) isolation, i.e., device isolation by a buried oxide film.

On one hand, attendant on the miniaturization of the device, the distance between the first n-type region n1 and the second n-type region n2 or the distance between the first p-type region p1 and the second p-type region p2 is shortened, so that punch-through is liable to be generated. Commonly, a silicide block region 321 is provided in order to maintain the distance between the first p-type region p1 and the second p-type region p2. According to this method, however, it is difficult to miniaturize the device in the horizontal directions.

On the other hand, there is a need for forming the first p-type region and the first n-type region n1 as a double diffusion layer. In this structure, however, when it is intended to thicken the first n-type region n1, punch-through would occur between the first n-type region n1 and the well, and, when the first n-type region n1 is too thin, punch-through would occur between the first p-type region p1 and the second p-type region. As a result, a considerably large process margin cannot be taken for the first n-type region n1, and, therefore, device characteristics are also limited.

[Patent Document 1]

U.S. Pat. No. 6,462,359 (B1)

[Non-patent Document 1]

Farid Nemati and James D. Plummer, “A Novel High Density, Low Voltage SRAM Cell with a Vertical NDR Device”, 1998 IEEE, VLSI Technology Tech. Dig., p. 66, 1998

[Non-patent Document 2]

Farid Nemati and James D. Plummer, “A Novel Thyristor-based SRAM Cell (T-RAM) for High-Speed, Low-Voltage, Giga-scale Memories”, 1999 IEEE IEDM Tech., p. 283, 1999

[Non-patent Document 3]

Farid Nemati, Hyun-Jin Cho, Scott Robins, Rajesh Cupta, Marc Tarabbia, Kevin J. Yang, Dennis Hayes, Vasudevan Gopalakrishnan, “Fully Planar 0.562 μm2 T-RAM Cell in a 130 nm SOI CMOS Logic Technology for High-Density High-Performance SRAMs”, 2004 IEEE IEDM Tech., p. 273, 2004

### SUMMARY OF THE INVENTION

Thus, there is the problem that it is difficult to secure scaling in the horizontal directions and to secure process margins for a double diffusion layer including the first p-type region p1 and the first n-type region n1.

Accordingly, there is a need to secure scaling in the horizontal directions and to secure process margins for a double diffusion layer including the first p-type region p1 and the first n-type region n1.

According to one embodiment of the present invention, there is provided a semiconductor device which has a thyristor including a first region of a first conduction type, a second region of a second conduction type opposite to the first conduction type, a third region of the first conduction type, and a fourth region of the second conduction type, in sequential junction, and has a gate electrode in the third region, the second region is formed in a part of the third region, and the first region is formed on the upper side of the second region.

In the semiconductor according to the one embodiment of the present invention, the first region of the first conduction type is stackedly formed on the upper side of the second region of the second conduction type. Therefore, the need for a silicide block needed in the past is eliminated, so that the cell area in the horizontal directions is reduced accordingly, which promises a reduction in the size of the device. In addition, since the first region of the first conduction type is formed on the upper side relative to the semiconductor substrate, it is possible to secure a margin in the thickness direction of the first region of the second conduction type between the second region of the first conduction type and the third region of the first conduction type.

According to another embodiment of the present invention, there is provided a semiconductor device which has a thyristor including a first region of a first conduction type, a second region of a second conduction type opposite to the first conduction type, a third region of the first conduction type, a fourth region of the second conduction type, in sequential junction, and has a gate electrode in the third region, wherein the second region is formed on the upper side of a part of the third region, and the first region is formed on the upper side of the second region.

In the semiconductor device according to the another embodiment of the present invention, the second region of the second conduction type is formed on the upper side of a part of the third region of the first conduction type, and, further, the first region of the first conduction type is stackedly formed on the upper side of the second region of the second conduction type. Therefore, the need for a silicide block needed in the past is eliminated, so that the cell area in the horizontal directions is reduced, which promises a reduction in the size of the device. Besides, since the first region of the first conduction type and the first region of the second conduction type are formed on the upper side relative to the semiconductor region, it is possible to secure a margin in the thickness direction of the second region of the second conduction type between the first region of the first conduction type and the third region of the first conduction type.

According to a further embodiment of the present invention, there is provided a method of manufacturing a semiconductor device which has a thyristor including a first region of a first conduction type, a second region of a second conduction type opposite to the first conduction type, a third region of the first conduction type, and a fourth region of the second conduction type, in sequential junction, and has a gate electrode at the third region, the method including the steps of: forming the second region in the semiconductor substrate, and forming the first region on the upper side of the second region.

In the method of manufacturing a semiconductor device according to the further embodiment of the present invention, the first region of the first conduction type is formed on the upper side of the second region of the second conduction type. Therefore, the need for a silicide block needed in the past is eliminated, so that the cell area in the horizontal directions is reduced accordingly, which promises a reduction in the size of the device. In addition, since the first region of the first conduction type is formed on the upper side relative to the semiconductor substrate, it is possible to secure a margin in the thickness direction of the second region of the second conduction type between the first region of the first conduction type and the third region of the first conduction type.

According to yet another embodiment of the present invention, there is provided a method of manufacturing a semiconductor device which has a thyristor including a first region of a first conduction type, a second region of a second conduction type opposite to the first conduction type, a third region of the first conduction type, and a fourth region of the second conduction type, in sequential junction, and has a gate electrode at the third region, the method including the steps of: forming the second region on the upper side of a part of the third region; and forming the first region on the upper side of the second region.

In the method of manufacturing a semiconductor device according to the yet another embodiment of the present invention, the second region of the second conduction type is formed on the upper side of the third region of the first conduction type, and, further, the first region of the first conduction type is stackedly formed on the upper side of the second region of the second conduction type. Therefore, the need for a silicide block needed in the past is eliminated, so that the cell area in the horizontal directions can be reduced, which promises a reduction in the size of the device. In addition, since the first region of the first conduction type and the second region of the second conduction type are formed on the upper side relative to the semiconductor substrate, it is possible to secure a margin in the thickness direction of the second region of the second conduction type between the first region of the first conduction type and the third region of the first conduction type.

In the semiconductor device according to the one embodiment of the present invention, the first region of the first conduction type is stackedly formed on the upper side of the second region of the second conduction type, so that a reduction in the device size can be achieved. In addition, since the first region of the first conduction type is formed on the upper side relative to the semiconductor substrate, it is possible to secure a margin in the thickness direction of the second region of the second conduction type between the first region of the first conduction type and the third region of the first conduction type, whereby punch-through resistance is enhanced advantageously.

In the semiconductor device according to the another embodiment of the present invention, the second region of the second conduction type is formed on the upper side of a part of the third region of the first conduction type, and the first region of the first conduction type is stackedly formed on the upper side of the second region of the second conduction type, so that a reduction in the device size can be realized. Besides, since the first region of the first conduction type and the second region of the second conduction type are formed on the upper side relative to the semiconductor substrate, it is possible to secure a margin in the thickness direction of the second region of the second conduction type between the first region of the first conduction type and the third region of the first conduction type, whereby punch-through resistance is enhanced advantageously.

In the method of manufacturing a semiconductor device according to the further embodiment of the present invention, the first region of the first conduction type is stackedly formed on the upper side of the second region of the second conduction type, so that a reduction in the device size can be achieved. In addition, since the first region of the first conduction type is formed on the upper side relative to the semiconductor device, it is possible to secure a margin in the thickness direction of the second region of the second conduction type between the first region of the first conduction type and the third region of the first conduction type, whereby punch-through resistance is enhanced advantageously.

In the method of manufacturing a semiconductor device according to the yet another embodiment of the present invention, the second region of the second conduction type is formed on the upper side of a part of the third region of the first conduction type, and, further, the first region of the first conduction type is stackedly formed on the upper side of the second region of the second conduction type, so that a reduction in the device size can be realized. Besides, since the first region of the first conduction type and the second region of the second conduction type are formed on the upper side relative to the semiconductor substrate, it is possible to secure a margin in the thickness direction of the second region of the second conduction type between the first region of the first conduction type and the third region of the first conduction type, whereby punch-through resistance is enhanced advantageously.

### BRIEF DESCRIPTION OF THE DRAWINGS

FIG. 1 is a schematic configuration sectional diagram showing a first example of one embodiment of the semiconductor device in the present invention;

FIG. 2 is a schematic configuration sectional diagram showing a modified example of the first example of one embodiment of the semiconductor device in the present invention;

FIG. 3 is a schematic configuration sectional diagram showing a second example of one embodiment of the semiconductor device in the present invention;

FIG. 4 is a schematic configuration sectional diagram showing a modified example of the second example of one embodiment of the semiconductor device in the present invention;

FIG. 5 is a schematic configuration sectional diagram showing a third example of one embodiment of the semiconductor device in the present invention;

FIG. 6 is a schematic configuration sectional diagram showing a modified example of the third example of one embodiment of the semiconductor device in the present invention;

FIG. 7 is a schematic configuration sectional diagram showing a fourth example of one embodiment of the semiconductor device in the present invention;

FIG. 8 is a schematic configuration sectional diagram showing a modified example of the fourth example of one embodiment of the semiconductor device in the present invention;

FIG. 9 is a schematic configuration sectional diagram showing a fifth example of one embodiment of the semiconductor device in the present invention;

FIG. 10 is a schematic configuration sectional diagram showing a modified example of the fifth example of one embodiment of the semiconductor device in the present invention;

FIG. 11 is a schematic configuration sectional diagram showing a sixth example of one embodiment of the semiconductor device in the present invention;

FIG. 12 is a schematic configuration sectional diagram showing a modified example of the sixth example of one embodiment of the semiconductor device in the present invention;

FIG. 13 is a schematic configuration sectional diagram showing a seventh example of one embodiment of the semiconductor device in the present invention;

FIG. 14 is a schematic configuration sectional diagram showing a modified example of the seventh example of one embodiment of the semiconductor device in the present invention;

FIG. 15 is a schematic configuration sectional diagram showing an eighth example of one embodiment of the semiconductor device in the present invention;

FIG. 16 is a schematic configuration sectional diagram showing a modified example of the eighth example of one embodiment of the semiconductor device in the present invention;

FIG. 17 is a schematic configuration sectional diagram showing a ninth example of one embodiment of the semiconductor device in the present invention;

FIG. 18 is a schematic configuration sectional diagram showing a modified example of the ninth example of one embodiment of the semiconductor device in the present invention;

FIG. 19 is a schematic configuration sectional diagram showing a tenth example of one embodiment of the semiconductor device in the present invention;

FIG. 20 is a schematic configuration sectional diagram showing an eleventh example of one embodiment of the semiconductor device in the present invention;

FIG. 21 is a schematic configuration sectional diagram showing a modified example of one embodiment of the semiconductor device in the present invention;

FIGS. 22A to 22C are manufacturing step sectional diagrams illustrating a first example of one embodiment of the method of manufacturing a semiconductor device in the present invention;

FIGS. 23A to 23C are manufacturing step sectional diagrams illustrating the first example of one embodiment of the method of manufacturing a semiconductor device in the present invention;

FIGS. 24A to 24D are manufacturing step sectional diagrams illustrating a second example of one embodiment of the method of manufacturing a semiconductor device in the present invention;

FIGS. 25A to 25C are manufacturing step sectional diagrams illustrating the second example of one embodiment of the method of manufacturing a semiconductor device in the present invention;

FIGS. 26A to 26C are manufacturing step sectional diagrams illustrating a modified example of the second example of one embodiment of the method of manufacturing a semiconductor device in the present invention;

FIGS. 27A to 27C are manufacturing step sectional diagrams illustrating the modified example of the second example of one embodiment of the method of manufacturing a semiconductor device in the present invention;

FIGS. 28A to 28C are manufacturing step sectional diagrams illustrating a third example of one embodiment of the method of manufacturing a semiconductor device in the present invention;

FIGS. 29A and 29B are manufacturing step sectional diagrams illustrating the third example of one embodiment of the method of manufacturing a semiconductor device in the present invention;

FIGS. 30A to 30C are manufacturing step sectional diagrams illustrating a fourth example of one embodiment of the method of manufacturing a semiconductor device in the present invention;

FIGS. 31A and 31B are manufacturing step sectional diagrams illustrating the fourth example of one embodiment of the method of manufacturing a semiconductor device in the present invention;

FIGS. 32A to 32C are manufacturing step sectional diagrams illustrating a modified example of the fourth example of one embodiment of the method of manufacturing a semiconductor device in the present invention;

FIGS. 33A and 33B are manufacturing step sectional diagrams illustrating the modified example of the fourth example of one embodiment of the method of manufacturing a semiconductor device in the present invention;

FIG. 34 is a manufacturing step sectional diagram illustrating a tenth example of one embodiment of the method of manufacturing a semiconductor device in the present invention;

FIG. 35 is a manufacturing step sectional diagram illustrating the tenth example of one embodiment of the method of manufacturing a semiconductor device in the present invention;

FIG. 36 is a manufacturing step sectional diagram illustrating the tenth example of one embodiment of the method of manufacturing a semiconductor device in the present invention;

FIG. 37 is a manufacturing step sectional diagram illustrating an eleventh example of one embodiment of the method of manufacturing a semiconductor device in the present invention;

FIG. 38 is a manufacturing step sectional diagram illustrating the eleventh example of one embodiment of the method of manufacturing a semiconductor device in the present invention;

FIG. 39 is a manufacturing step sectional diagram illustrating the eleventh example of one embodiment of the method of manufacturing a semiconductor device in the present invention;

FIGS. 40A to 40C are a configuration diagram and operation illustrations of a semiconductor device of a thyristor configuration according to the related art;

FIG. 41 is a voltage-current characteristic diagram showing the voltage-current (V-I) characteristic of a semiconductor device of a thyristor configuration according to the related art; and

FIG. 42 is a schematic configuration sectional diagram illustrating a problem in a semiconductor device of a thyristor configuration according to the related art.

### DETAILED DESCRIPTION OF THE PREFERRED EMBODIMENTS

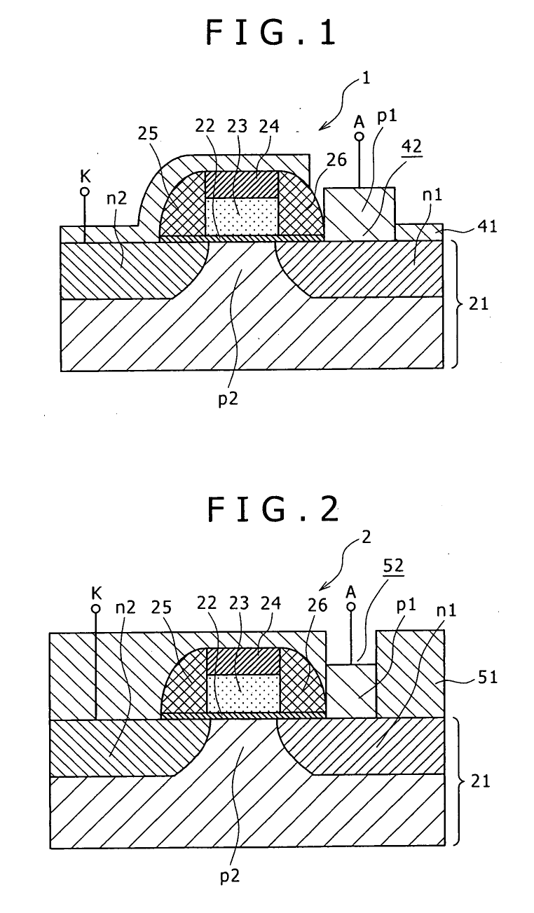

Now, a first example of one embodiment of the semiconductor device in the present invention will be described below, referring to a schematic configuration sectional diagram shown in FIG. 1.

As shown in FIG. 1, the semiconductor device 1 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over (on the upper side of) the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃)

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The semiconductor substrate 21 on one side of the gate electrode 23 is provided with the first n-type region n1 of the second conduction type (n-type) which is in junction with the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

The semiconductor substrate 21 on the other side of the gate electrode 23 is provided with the second n-type region n2 of the second conduction type (n-type) which is in junction with the second p-type region p2. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, a first insulating film 41 is formed to cover the gate electrode 23, the hard mask 24, the side walls 25, 26 and the like. The first insulating film 41 is composed, for example, of a silicon nitride film in a thickness of, for example, 20 nm. In addition, the first insulating film 41 over the first n-type region n1 is provided with an opening part 42. The first p-type region p1 of the first conduction type (p-type) is formed in the opening part 42 over the first n-type region n1. The first p-type region p1 is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. The film thickness is desirably in the range of about 50 to 300 nm, but it suffices for the thickness to be in such a range that the first p-type region p1 can function as an anode.

Further, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 1 in the present invention, a reduction in the device size can be realized, since the first p-type region p1 is stackedly formed over the first n-type region n1. Besides, since the first p-type region p1 is formed above (on the upper side relative to) the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 1 is a promising device even as one of the devices of the coming generations.

In the next place, a modified example of the first example of one embodiment of the semiconductor device in the present invention will be described, referring to a schematic configuration sectional diagram shown in FIG. 2. This modified example is an example in which the epitaxial growth in the above-described first example is made in a hole.

As shown in FIG. 2, the semiconductor device 2 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The semiconductor substrate 21 on one side of the gate electrode 23 is provided with the first n-type region n1 of the second conduction type (n-type) which is in junction with the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

The semiconductor substrate 21 on the other side of the gate electrode 23 is provided with the second n-type region n2 of the second conduction type (n-type) which is in junction with the second p-type region p2. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, a first insulating film 51 is formed to cover the gate electrode 23, the hard mask 24, the side walls 25, 26 and the like. The first insulating film 51 is composed, for example, of a silicon oxide film (e.g., a high-density plasma silicon oxide film) in a thickness of, for example, 500 nm, and with a surface planarized, for example. Besides, the first insulating film 51 over the first n-type region n1 is provided with an opening part (hole) 52. The first p-type region p1 of the first conduction type (p-type) is formed in the opening part 52 over the first n-type region n1. The first p-type region p1 is formed, for example, by selective epitaxial growth in a film thickness of, for example, 200 nm and with a boron (B) concentration in film of, for example, 1×10²⁰ cm⁻³. The dopant (boron) concentration is desirably in the range of 1×10¹⁸ to 1×10²¹ cm⁻³. Besides, the film thickness is desirably in the range of about 50 to 300 nm, but it suffices for the thickness to be in such a range that the first p-type region p1 can function as an anode.

Further, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 2 in the present invention, a reduction in the device size can be realized more than in the above-described first example, since the first p-type region p1 is self-alignedly stackedly formed in the opening part 52 over the first n-type region n1. Besides, since the first p-type region p1 is formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 2 is a promising device even as one of the devices of the coming generations.

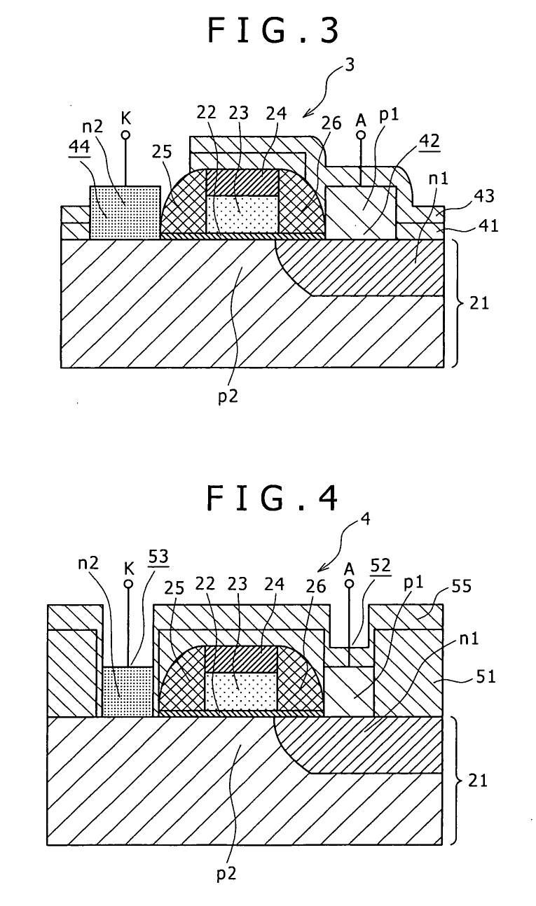

Now, a second example of one embodiment of the semiconductor device in the present invention will be described below, referring to a schematic configuration sectional view shown in FIG. 3.

As shown in FIG. 3, the semiconductor device 3 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The semiconductor substrate 21 on one side of the gate electrode 23 is provided with the first n-type region n1 of the second conduction type (n-type) which is in junction with the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

In addition, a first insulating film 41 is formed to cover the gate electrode 23, the hard mask 24, the side walls 25, 26 and the like. The first insulating film 41 is composed, for example, of a silicon nitride film in a thickness of, for example, 20 nm. Besides, the first insulating film 41 over the first n-type region n1 is provided with an opening part 42. The first p-type region p1 of the first conduction type (p-type) is formed in the opening part 42 over the first n-type region n1. The first p-type region p1 is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. The film thickness is desirably in the range of about 50 to 300 nm, but it suffices for the thickness to be in such a range that the first p-type region p1 can function as an anode.

In addition, a second insulating film 43 is formed to cover the gate electrode 23, the hard mask 24, the side walls 25, 26, the first p-type region p1 and the like. The second insulating film 43 is composed, for example, of a silicon nitride film in a thickness of, for example, 20 nm. Besides, the second insulating film 43 and the first insulating film 41 in the region where the second n-type region is to be formed are provided with an opening part 44. The second n-type region 2 of the second conduction type (n-type) is formed in the opening part 44. The second n-type region n2 is formed by implanting, for example, arsenic (As) as an n-type dopant in a dopant concentration of, for example, 1×10²⁰ cm⁻³, and in a thickness of, for example, 200 nm. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Further, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 3 in the present invention, a reduction in the device size can be realized, since the first p-type region p1 is stackedly formed over the first n-type region n1 and, further, the second n-type region n2 is stackedly formed over the second p-type region p2. Besides, since the first p-type region p1 is formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 3 is a promising device even as one of the devices of the coming generations.

In the next place, a modified example of the second example of one embodiment of the semiconductor device in the present invention will be described, referring to a schematic configuration sectional diagram shown in FIG. 4. This modified example is an example in which the epitaxial growth in the above-described second example is made in a hole.

As shown in FIG. 4, the semiconductor device 4 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

Furthermore, a first insulating film 51 is formed to cover the gate electrode 23, the hard mask 24, the side walls 25, 26 and the like. The first insulating film 51 is composed, for example, of a silicon oxide film (e.g., a high-density plasma silicon oxide film) in a thickness of, for example, 500 nm, and with a surface planarized, for example. Besides, the first insulating film 51 over the first n-type region n1 is provided with an opening part (hole) 52. The first p-type region p1 of the first conduction type (p-type) is formed in the opening part 52 over the first n-type region n1. Incidentally, though not shown, the side walls of the opening part 52 may be coated, for example, with a silicon nitride film for further enhancing selectivity in selective epitaxial growth. The first p-type region p1 is formed, for example, by selective epitaxial growth in a film thickness of, for example, 200 nm and with a boron (B) concentration in film of, for example, 1×10²⁰ cm⁻³. The dopant (boron) concentration is desirably in the range of 1×10¹⁸ to 1×10²¹ cm⁻³. Besides, the film thickness is desirably in the range of about 50 to 300 nm, but it suffices for the thickness to be in such a range that the first p-type region p1 can function as an anode.

In addition, the first insulating film 51 on the opposite side of the first p-type region p1 with respect to the gate electrode 23 is provided with an opening part (hole) 53. A second insulating film 55 composed of a silicon nitride film may be formed over the surfaces of the first insulating film 51, inclusive of the inside surfaces of the opening part 53. In this case, the second insulating film 55 at a bottom part of the opening part 53 is removed. Then, the second n-type region n2 of the second conduction type (n-type) which is in junction with the second p-type region p2 is formed in the inside of the opening part 53. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Further, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 4 in the present invention, a reduction in the device size can be realized more than in the above-described third example, since the first p-type region p1 is self-alignedly stackedly formed in the opening part 52 over the first n-type region n1 and, further, the second n-type region n2 is self-alignedly stacked in the opening part 53 over the second p-type region p2. Besides, since the first p-type region p1 is formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 4 is a promising device even as one of the devices of the coming generations.

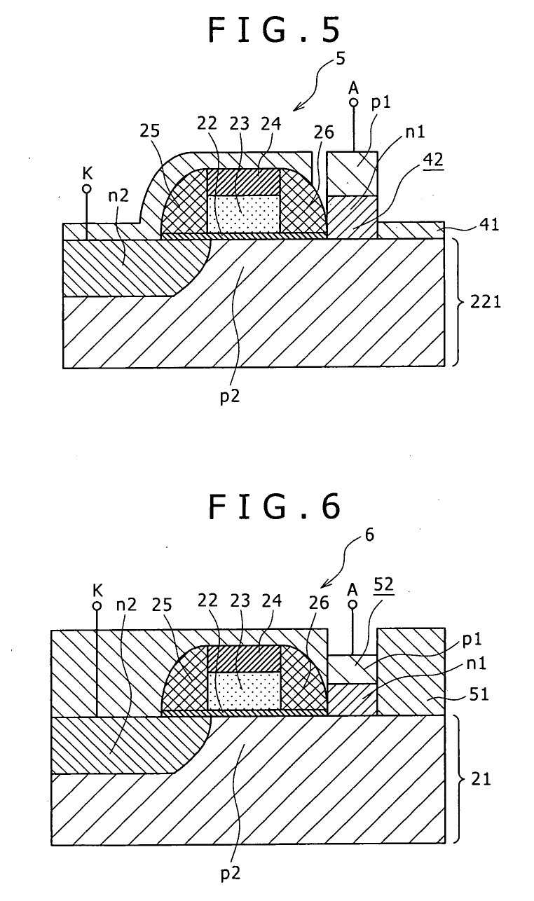

Now, a third examples of one embodiment of the semiconductor device in the present invention will be described below, referring to a schematic configuration sectional diagram shown in FIG. 5.

As shown in FIG. 5, the semiconductor device 5 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The semiconductor substrate 21 on the other side of the gate electrode 23 is provided with the second n-type region n2 of the second conduction type (n-type) which is in junction with the second p-type region p2. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, a first insulating film 41 is formed to cover the gate electrode 23, the hard mask 24, the side walls 25, 26 and the like. The first insulating film 41 is composed, for example, of a silicon nitride film in a thickness of, for example, 20 nm. In addition, the first insulating film 41 over the second p-type region p2 on one side (the right side in the figure) of the gate electrode 23, with the side wall 26 therebetween, is provided with an opening part 42. The first n-type region n1 of the second conduction type (n-type) which is in junction with the second p-type region p2 is formed in the opening part 42 over the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

Further, the first p-type region p1 of the first conduction type (p-type) is formed over the first n-type region n1. The first p-type region is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. The film thickness is desirably in the range of about 50 to 300 nm, but it suffices for the thickness to be in such a range that the first p-type region p1 can function as an anode.

Furthermore, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 5, a reduction in the device size can be realized, since the first n-type region n1 is formed over a part of the second p-type region p2 and, further, the first p-type region p1 is stackedly formed over the first n-type region n1. Besides, since the first p-type region p1 and the first n-type region n1 are formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 5 is a promising device even as one of the devices of the coming generations.

In the next place, a modified example of the third example of one embodiment of the semiconductor device in the present invention will be described, referring to a schematic configuration sectional diagram shown in FIG. 6. This example is an example in which the epitaxial growth in the third embodiment above is made in a hole.

As shown in FIG. 6, the semiconductor device 6 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The semiconductor substrate 21 on one side (the left side in the figure) of the gate electrode 23 is provided with the second n-type region n2 of the second conduction type (n-type) which is in junction with the second p-type region p2. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, a first insulating film 51 is formed to cover the gate electrode 23, the hard mask 24, the side walls 25, 26 and the like. The first insulating film 51 is composed, for example, of a silicon oxide film (e.g., a high-density plasma silicon oxide film) in a thickness of, for example, 500 nm, and with a surface planarized, for example. Besides, the first insulating film 51 over the second p-type region p2 on one side (the right side in the figure), with the side wall 26 therebetween, is provided with an opening part (hole) 52. A silicon nitride film (not shown) for further enhancing selectivity in selective epitaxial growth may be formed on side walls of the opening part 52. The first n-type region n1 of the second conduction type (n-type) in junction with the second p-type region p2 is formed in the opening part 52 over the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of 1×10¹⁸to 1×10²¹ cm⁻³, and should be higher than the dopant concentration in the second p-type region p2. Other n-type dopants such as arsenic, antimony, etc. may be used, in place of phosphorus. Besides, the film thickness of the first n-type region n1 is desirably in the range of about 50 to 300 nm; as an example, the film thickness was set to 100 nm.

Further, the first p-type region p1 of the first conduction type (p-type) is formed over the first n-type region n1. The first p-type region p1 is formed, for example, by selective epitaxial growth in a film thickness of, for example, 200 nm and with a boron (B) concentration in film of 1×10²⁰ cm⁻³. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Furthermore, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 6, a reduction in the device size can be realized, since the first n-type region n1 is stackedly formed over a part of the second p-type region p2 and, further, the first p-type region p1 is stackedly formed over the first n-type region n1. Moreover, since the first n-type region n1 and the first p-type region are self-alignedly formed in the opening part 52, a further reduction in cell area can be attained. Besides, since the first p-type region p1 and the first n-type region n1 are formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 6 is a promising device even as one of the devices of the coming generations.

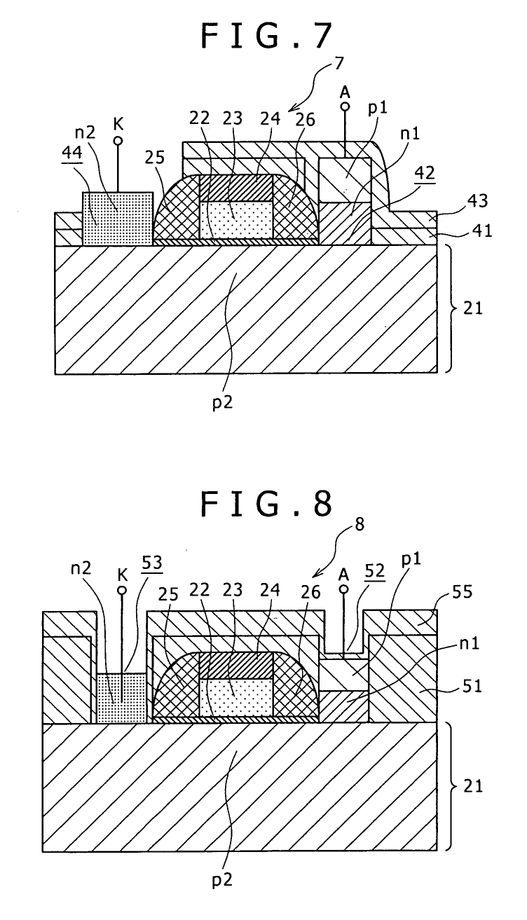

Now, a fourth examples of one embodiment of the semiconductor device in the present invention will be described below, referring to a schematic configuration sectional diagram shown in FIG. 7.

As shown in FIG. 7, the semiconductor device 7 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

Furthermore, a first insulating film 41 is formed to cover the gate electrode 23, the hard mask 24, the side walls 25, 26 and the like. The first insulating film 41 is composed, for example, of a silicon nitride film in a thickness of, for example, 20 nm. In addition, the first insulating film 41 over the second p-type region p2 on one side (the right side in the figure) of the gate electrode 23, with the side wall 26 therebetween, is provided with an opening part 42. The first n-type region n1 of the second conduction type (n-type) which is in junction with the second p-type region p2 is formed in the opening part 42 over the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

Further, the first p-type region p1 of the first conduction type (p-type) is formed over the first n-type region n1. The first p-type region is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Furthermore, a second insulating film 43 is formed to cover the gate electrode 23, the hard mask 24, the side walls 25, 26, the first p-type region p1 and the like. The second insulating film 43 is composed, for example, of a silicon nitride film in a thickness of, for example, 20 nm. Besides, the first insulating film 41 and the second insulating film 43 over the second p-type region p2 on the other side (the left side in the figure) of the gate electrode 23, with the side wall 25 therebetween, are provided with an opening part 44.

The second n-type region n2 of the second conduction type (n-type) which is in junction with the second p-type region p2 is formed in the opening part 44 over the second p-type region p2. The second n-type region n2 is formed by implanting, for example, arsenic (As) as an n-type dopant in a dopant concentration of, for example, about 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 7, a reduction in the device size can be realized, since the first n-type region n1 and the first p-type region p1 are sequentially stackedly formed over a part of the second p-type region p2 and, further, the second n-type region n2 is stackedly formed over the second p-type region p2. In addition, since the first p-type region p1 and the first n-type region n1 are formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics are attained, and the semiconductor device 7 is a promising device even as one of the devices of the coming generations.

In the next place, a modified example of the fourth example of one embodiment of the semiconductor device in the present invention will be described, referring to a schematic configuration sectional diagram shown in FIG. 8. This example is an example in which the epitaxial growth in the fourth embodiment above is made in a hole.

As shown in FIG. 8, the semiconductor device 8 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A semiconductor substrate 21 is provided with an element isolating region (not shown) for isolating an element forming region. At least an upper layer of the element forming region in the semiconductor substrate 21 is formed in the region of the first conduction type (p-type), and this region constitutes the second p-type region p2 of a thyristor. As the semiconductor substrate 21, for example, a silicon substrate is used. The second p-type region p2 is formed by implanting, for example, boron (B) as a p-type dopant in a dopant concentration of about 5×10¹⁸ cm⁻³. The dopant concentration in the second p-type region p2 is desirably in the range of about 1×10^{l8} to 1×10^{l9} cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

Furthermore, a first insulating film 51 is formed to cover the gate electrode 23, the hard mask 24, the side walls 25, 26 and the like. The first insulating film 51 is composed, for example, of a silicon oxide film (e.g., a high-density plasma silicon oxide film) in a thickness of, for example, 500 nm, and with a surface planarized, for example. Besides, the first insulating film 51 over the second p-type region p2 on one side (the right side in the figure), with the side wall 26 therebetween, is provided with an opening part (hole) 52. The first n-type region n1 of the second conduction type (n-type) in junction with the second p-type region p2 is formed in the opening part 52 over the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of 1×10¹⁸ to 1×10²¹ cm⁻³, and should be higher than the dopant concentration in the second p-type region p2. Other n-type dopants such as arsenic, antimony, etc. may be used, in place of phosphorus. Besides, the film thickness of the first n-type region n1 is desirably in the range of about 50 to 300 nm; as an example, the film thickness was set to 100 nm.

Further, the first p-type region p1 of the first conduction type (p-type) is formed over the first n-type region n1. The first p-type region p1 is formed, for example, by selective epitaxial growth in a film thickness of, for example, 200 nm and with a boron (B) concentration in film of 1×10²⁰ cm⁻³. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Furthermore, the first insulation film 51 over the second p-type region p2 on the other side (the left side in the figure) of the gate electrode 23, with the side wall 25 therebetween, is provided with an opening part (hole) 53. Further, a second insulating film 55 is formed to cover the first insulating film 51, the first p-type region p1 and the like. The second insulating film 55 is composed, for example, of a silicon nitride film in a thickness of, for example, 20 nm. Besides, the second insulating film 55 at a bottom portion of the opening part 53 is removed.

The second n-type region n2 of the second conduction type (n-type) which is in junction with the second p-type region p2 is formed in the opening part 53 over the second p-type region p2. The second n-type region n2 is formed by implanting, for example, arsenic (As) as an n-type dopant in a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Further, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 8, a reduction in the device size can be realized, since the first n-type region n1 and the first p-type region p1 are sequentially stackedly formed over a part of the second p-type region p2 and, further, the second n-type region n2 is stackedly formed over the second p-type region p2. Moreover, since the first n-type region n1 and the first p-type region are self-alignedly formed in the opening part 52 and the second n-type region n2 is self-alignedly formed in the opening part 52, a further reduction in cell area can be attained. Besides, since the first p-type region p1 and the first n-type region n1 are formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 8 is a promising device even as one of the devices of the coming generations.

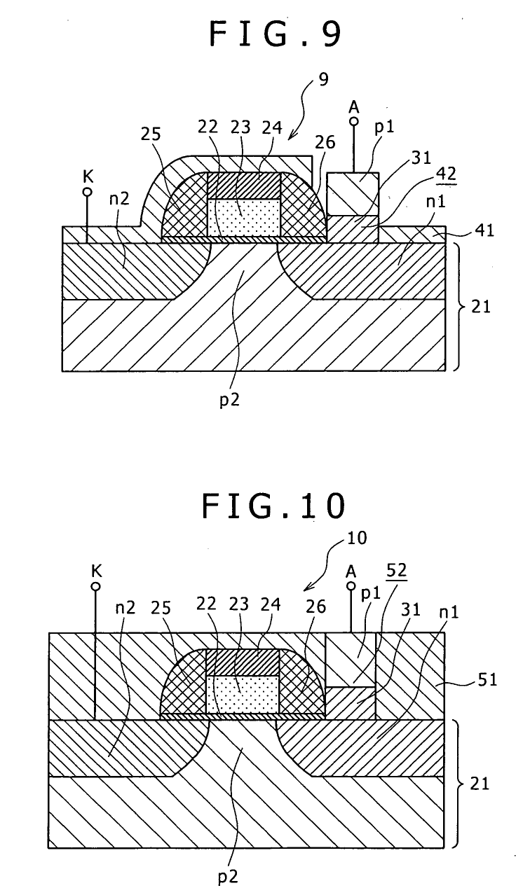

Now, a fifth example of one embodiment of the semiconductor device in the present invention will be described below, referring to a schematic configuration sectional diagram shown in FIG. 9.

As shown in FIG. 9, the semiconductor device 9 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 9 has a configuration in which, in the semiconductor device 1 described referring to FIG. 1 above, a diffusion preventive layer 31 having a dopant concentration comparable to that in the first n-type region n1 is formed over the first n-type region n1 by use of, for example, an n-type epitaxial layer in a thickness of 10 to 50 nm, and the first p-type region p1 is formed over the diffusion preventive layer 31. Therefore, the semiconductor substrate 21, the gate insulating film 22, the gate electrode 23, the hard mask 24, the side walls 25, 26, the first insulating film 41, the opening part 42 and the like are the same as in the configuration described referring to FIG. 1 above.

In the semiconductor device 9, it is possible to restrain the impurity in the first p-type region p1 from diffusing to the side of the semiconductor substrate 21, since the diffusion preventive layer 31 composed, for example, of the n-type epitaxial layer is formed over the first n-type region n1 and the first p-type region p1 is formed over the diffusion preventive layer 31. In addition, the same effects as those of the semiconductor device 1 according to the first example above can be obtained. Further, since the diffusion preventive layer 31 is formed under (on the lower side of) the first p-type region p1, the cell area is not increased due to the formation of the diffusion preventive layer 31.

In the next place, a modified example of the fifth example of one embodiment of the semiconductor device in the present invention will be described, referring to a schematic configuration sectional diagram shown in FIG. 10. This modified example is an example in which the epitaxial growth in the fifth example above is made in the inside of a hole.

As shown in FIG. 10, the semiconductor device 10 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 10 has a configuration in which, in the semiconductor device 2 described referring to FIG. 2 above, a diffusion preventive layer 31 having a dopant concentration comparable to that in the first n-type region n1 is formed over the first n-type region n1 by use of, for example, an n-type epitaxial layer in a thickness of 10 to 50 nm, and the first p-type region p1 is formed over the diffusion preventive layer 31. Therefore, the semiconductor substrate 21, the gate insulating film 22, the gate electrode 23, the hard mask 24, the side walls 25, 26, the first insulating film 51, the opening part 52 and the like are the same as in the configuration described referring to FIG. 2 above.

In the semiconductor device 10, it is possible to restrain the impurity in the first p-type region p1 from diffusing to the side of the semiconductor substrate 21, since the diffusion preventive layer 31 composed, for example, of the n-type epitaxial layer is formed over the first n-type region n1 and the first p-type region p1 is formed over the diffusion preventive layer 31. In addition, the same effects as those of the semiconductor device 2 according to the second example above can be obtained. Further, since the diffusion preventive layer 31 composed, for example, of the n-type epitaxial layer and the first p-type region p1 are self-alignedly formed in the inside of the opening part 52, the cell area is not increased due to the formation of the diffusion preventive layer 31.

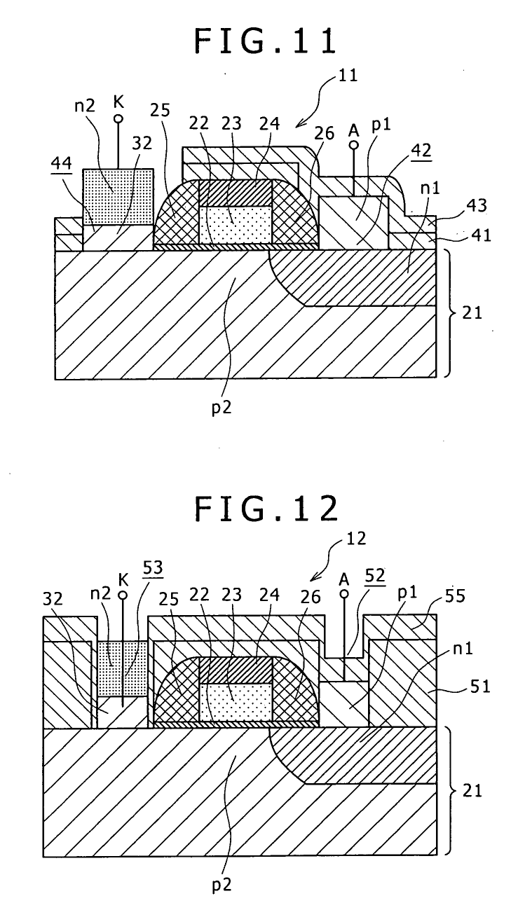

Now, a sixth example of one embodiment of the semiconductor device in the present invention will be described below, referring to a schematic configuration sectional diagram shown in FIG. 11.

As shown in FIG. 11, the semiconductor device 11 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 11 has a configuration in which, in the semiconductor device 3 described referring to FIG. 3 above, a diffusion preventive layer 32 having a dopant concentration comparable to that in the second p-type region p2 is formed over the second p-type region p2 in the area where the second n-type region n2 is to be formed, by use of, for example, a p-type epitaxial layer in a thickness of 10 to 50 nm, and the second n-type region n2 is formed over the diffusion preventive layer 32. Therefore, the semiconductor substrate 21, the gate insulating film 22, the gate electrode 23, the hard mask 24, the side walls 25, 26, the first insulating film 41, the opening part 42, the second insulating film 43, the opening part 44 and the like are the same as in the configuration described referring to FIG. 3 above.

In the semiconductor device 11, it is possible to restrain the impurity in the second n-type region n2 from diffusing into the semiconductor substrate 21, since the diffusion preventive layer 32 composed, for example, of the p-type epitaxial layer is formed over the second p-type region p2 in the area where the second n-type region n2 is to be formed and the second n-type region n2 is formed over the diffusion preventive layer 32. In addition, the same effects as those of the semiconductor device 3 according to the third example above can be obtained. Further, since the diffusion preventive layer 32 is formed under the second n-type region n2, the cell area is not increased due to the formation of the diffusion preventive layer 32.

In the next place, a modified example of the sixth example of one embodiment of the semiconductor device in the present invention will be described, referring to a schematic configuration sectional diagram shown in FIG. 12. This modified example is an example in which the epitaxial growth in the sixth example above is made in the inside of a hole.

As shown in FIG. 12, the semiconductor device 12 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 12 has a configuration in which, in the semiconductor device 4 described referring to FIG. 4 above, a diffusion preventive layer 32 having a dopant concentration comparable to that in the second p-type region p2 is formed over the second p-type region p2 in the area where the second n-type region n2 is to be formed, by use of, for example, a p-type epitaxial layer in a thickness of 10 to 50 nm, and the second n-type region n2 is formed over the diffusion preventive layer 32. Therefore, the semiconductor substrate 21, the gate insulating film 22, the gate electrode 23, the hard mask 24, the side walls 25, 26, the first insulating film 51, the opening parts 52, 53, the second insulating film 55 and the like are the same as in the configuration described referring to FIG. 4 above.

In the semiconductor device 12, it is possible to restrain the impurity in the second n-type region n2 from diffusing to the side of the semiconductor substrate 21, since the diffusion preventive layer 32 composed, for example, of the p-type epitaxial layer is formed over the second p-type region p2 in the area where the second n-type region n2 is to be formed and the second n-type region n2 is formed over the diffusion preventive layer 32. In addition, the same effects as those of the semiconductor device 4 according to the fourth example above can be obtained. Further, since the diffusion preventive layer 32 and the second n-type region n2 are self-alignedly formed in the inside of the opening part 53, the cell area is not increased due to the formation of the diffusion preventive layer 32.

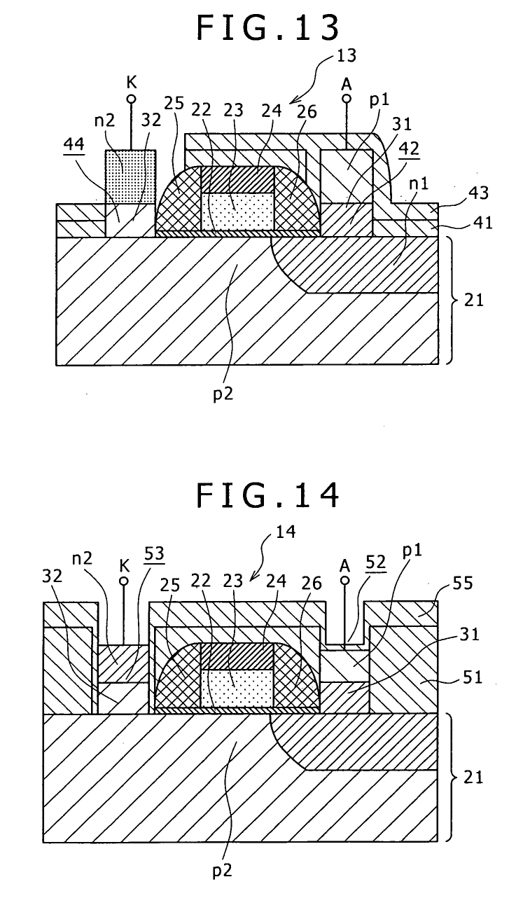

Now, a seventh example of one embodiment of the semiconductor device in the present invention will be described below, referring to a schematic configuration sectional diagram shown in FIG. 13.

As shown in FIG. 13, the semiconductor device 13 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 13 has a configuration in which, in the semiconductor device 3 described referring to FIG. 3 above, a diffusion preventive layer 31 having a dopant concentration comparable to that in the first n-type region n1 is formed over the first n-type region n1 by use of, for example, an n-type epitaxial layer in a thickness of 10 to 50 nm, and the first p-type region p1 is formed over the diffusion preventive layer 31. Further, a diffusion preventive layer 32 having a dopant concentration comparable to that in the second p-type region p2 is formed on the second p-type region p2 in the area where the second n-type region n2 is to be formed, by use of, for example, a p-type epitaxial layer in a thickness of 10 to 50 nm, and the second n-type region n2 is formed over the diffusion preventive layer 32. Therefore, the semiconductor substrate 21, the gate insulating film 22, the gate electrode 23, the hard mask 24, the side walls 25, 26, the first insulating film 41, the opening part 42, the second insulating film 43, the opening part 44 and the like are the same as in the configuration described referring to FIG. 3 above.

In the semiconductor device 13, it is possible to restrain the impurity in the first p-type region p1 from diffusing to the side of the semiconductor substrate 21, since the diffusion preventive layer 31 composed, for example, of the n-type epitaxial layer is formed over the first n-type region n1 and the first p-type region p1 is formed over the diffusion preventive layer 31. Besides, it is possible to restrain the impurity in the second n-type region n2 from diffusing to the side of the semiconductor substrate 21, since the diffusion preventive layer 32 composed, for example, of the p-type epitaxial layer is formed over the second p-type region p2 in the area where the second n-type region n2 is to be formed and the second n-type region n2 is formed over the diffusion preventive layer 32. Further, the same effects as those of the semiconductor device 3 according to the third example above can be obtained.

In the next place, a modified example of the seventh example of one embodiment of the semiconductor device in the present invention will be described, referring to a schematic configuration sectional diagram shown in FIG. 14. This modified example is an example in which the epitaxial growth in the seventh example above is made in the inside of a hole.

As shown in FIG. 14, the semiconductor device 14 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 14 has a configuration in which, in the semiconductor device 4 described referring to FIG. 4 above, a diffusion preventive layer 31 having a dopant concentration comparable to that in the first n-type region n1 is formed over the first n-type region n1 by use of, for example, an n-type epitaxial layer in a thickness of 10 to 50 nm, and the first p-type region p1 is formed over the diffusion preventive layer 31. Further, a diffusion preventive layer 32 having a dopant concentration comparable to that in the second p-type region p2 is formed on the second p-type region p2 in the area where the second n-type region n2 is to be formed, by use of, for example, a p-type epitaxial layer in a thickness of 10 to 50 nm, and the second n-type region n2 is formed over the diffusion preventive layer 32. Therefore, the semiconductor substrate 21, the gate insulating film 22, the gate electrode 23, the hard mask 24, the side walls 25, 26, the first insulating film 51, the opening parts 52, 53, the second insulating film 55 and the like are the same as in the configuration described referring to FIG. 4 above.

In the semiconductor device 14, it is possible to restrain the impurity in the first p-type region p1 from diffusing to the side of the semiconductor substrate 21, since the diffusion preventive layer 31 composed, for example, of the n-type epitaxial layer is formed over the first n-type region n1 and the first p-type region p1 is formed over the diffusion preventive layer 31. Besides, it is possible to restrain the impurity in the second n-type region n2 from diffusing to the side of the semiconductor substrate 21, since the diffusion preventive layer 32 composed, for example, of the p-type epitaxial layer is formed over the second p-type region p2 in the area where the second n-type region n2 is to be formed and the second n-type region n2 is formed over the diffusion preventive layer 32. Further, the same effects as those of the semiconductor device 4 according to the fourth example above can be obtained. Furthermore, since the diffusion preventive layer 31 and the first p-type region p1 are self-alignedly formed in the inside of the opening part 52, the cell area is not increased due to the formation of the diffusion preventive layer 31. Besides, since the diffusion preventive layer 32 and the second n-type region n2 are self-alignedly formed in the inside of the opening part 53, the cell area is not increased due to the formation of the diffusion preventive layer 32.

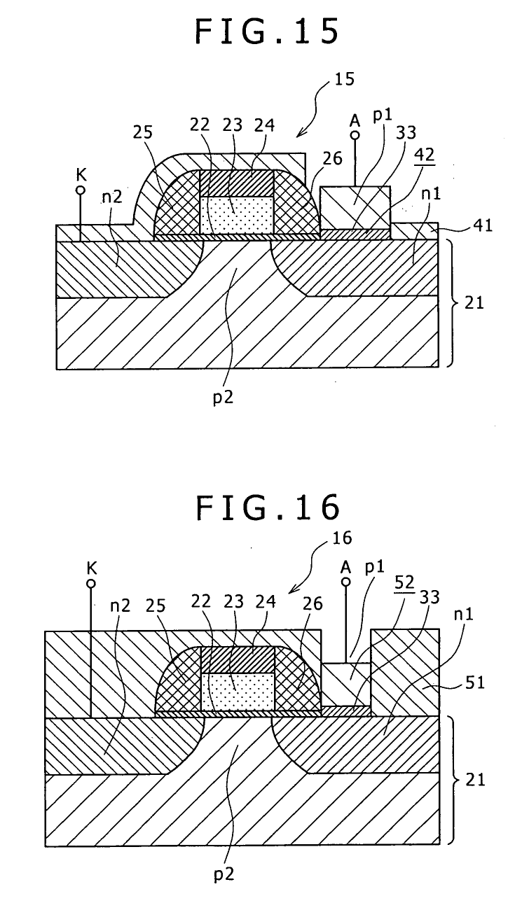

Now, an eighth example of one embodiment of the semiconductor device in the present invention will be described below, referring to a schematic configuration sectional diagram shown in FIG. 15.

As shown in FIG. 15, the semiconductor device 15 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 15 has a configuration in which, in the semiconductor device 1 described referring to FIG. 1 above, a low-concentration region 33 is formed over the first n-type region n1, and the first p-type region p1 is formed over the low-concentration region 33. The low-concentration region 33 is composed of a non-doped layer, a second conduction type (n-type) low-concentration region lower in dopant concentration than the first n-type region n1, or a first conduction type (p-type) low-concentration region lower in dopant concentration than the first p-type region p1. For example, in the case of the second conduction type (n-type) low-concentration region, it is formed to have a dopant concentration lower by about one or two orders than the dopant concentration in the first n-type region n1; in the case of the first conduction type (p-type) low-concentration region, it is formed to have a dopant concentration lower by about one or two orders than the dopant concentration in the first p-type region p1. In addition, the low-concentration region is formed in a film thickness of, for example, about 10 to 50 nm. Therefore, the semiconductor substrate 21, the gate insulating film 22, the gate electrode 23, the hard mask 24, the side walls 25, 26, the first insulating film 41, the opening 42 and the like are the same as in the configuration described referring to FIG. 1 above.

In the semiconductor device 15, since the low-concentration region 33 is formed over the first n-type region n1 and the first p-type region p1 is formed over the low-concentration region 33, an electric field is moderated, withstand voltage performance is thereby enhanced, and an enhanced retention of the thyristor itself can be expected. Besides, the same effects as those of the semiconductor device 1 according to the first example above can be obtained.

In the next place, a modified example of the eighth example of one embodiment of the semiconductor device in the present invention will be described, referring to a schematic configuration sectional diagram shown in FIG. 16. This modified example is an example in which the epitaxial growth in the eighth example above is made in the inside of a hole.

As shown in FIG. 16, the semiconductor device 16 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 16 has a configuration in which, in the semiconductor device 2 described referring to FIG. 2 above, a low-concentration region 33 is formed over the first n-type region n1, and the first p-type region p1 is formed over the low-concentration region 33. The low-concentration region 33 is composed of a non-doped layer, a second conduction type (n-type) low-concentration region lower in dopant concentration than the first n-type region n1, or a first conduction type (p-type) low-concentration region lower in dopant concentration than the first p-type region p1. For example, in the case of the second conduction type (n-type) low-concentration region, it is formed to have a dopant concentration lower by about one or two orders than the dopant concentration in the first n-type region n1; in the case of the first conduction type (p-type) low-concentration region, it is formed to have a dopant concentration lower by about one or two orders than the dopant concentration in the first p-type region p1. In addition, the low-concentration region is formed in a film thickness of, for example, about 10 to 50 nm. Therefore, the semiconductor substrate 21, the gate insulating film 22, the gate electrode 23, the hard mask 24, the side walls 25, 26, the first insulating film 51, the opening 52 and the like are the same as in the configuration described referring to FIG. 2 above.

In the semiconductor device 16, since the low-concentration region 33 is formed over the first n-type region n1 and the first p-type region p1 is formed over the low-concentration region 33, an electric field is moderated, withstand voltage performance is thereby enhanced, and an enhanced retention of the thyristor itself can be expected. Besides, the same effects as those of the semiconductor device 2 according to the second example above can be obtained. Furthermore, since the low-concentration region 33 and the first p-type region p1 are self-alignedly formed in the inside of the opening part 52, the cell area is not increased due to the formation of the low-concentration region 33.

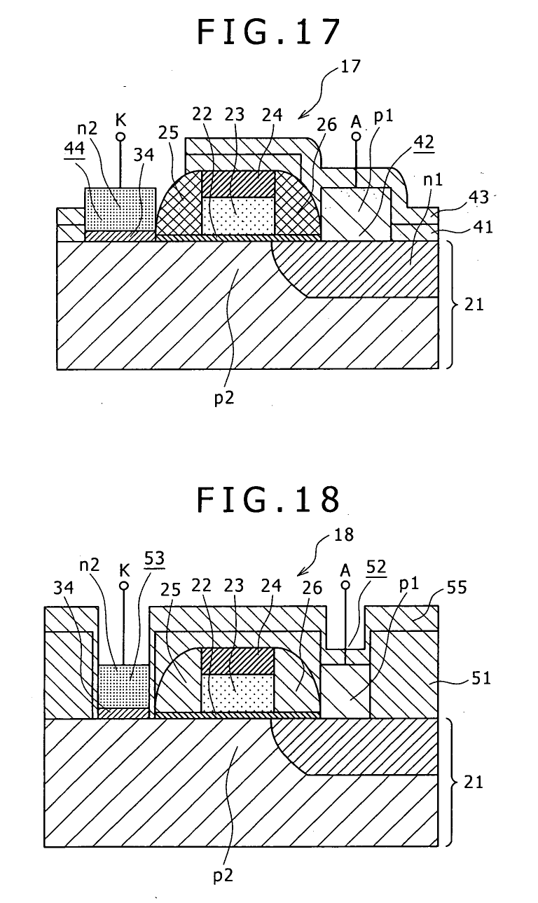

Now, a ninth example of one embodiment of the semiconductor device in the present invention will be described below, referring to a schematic configuration sectional diagram shown in FIG. 17.

As shown in FIG. 17, the semiconductor device 17 has a thyristor structure including a first region (hereinafter referred to as the first p-type region) p1 of a first conduction type (hereinafter referred to as p-type), a second region hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction.

The semiconductor device 17 has a configuration in which, in the semiconductor device 3 described referring to FIG. 3 above, a low-concentration region 34 is formed over the second p-type region p2 in the area where the second n-type region n2 is to be formed, and the second n-type region n2 is formed over the low-concentration region 34. The low-concentration region 34 is composed of a non-doped layer, a second conduction type (n-type) low-concentration region lower in dopant concentration than the second n-type region n2, or a first conduction type (p-type) low-concentration region lower in dopant concentration than the second p-type region p2. For example, in the case of the second conduction type (n-type) low-concentration region, it is formed to have a dopant concentration lower by about one or two orders than the dopant concentration in the second n-type region n2; in the case of the first conduction type (p-type) low-concentration region, it is formed to have a dopant concentration lower by about one or two orders than the dopant concentration in the second p-type region p2. In addition, the low-concentration region is formed in a film thickness of, for example, about 10 to 50 nm. Therefore, the semiconductor substrate 21, the gate insulating film 22, the gate electrode 23, the hard mask 24, the side walls 25, 26, the first insulating film 41, the opening 42, the second insulating film 43, the opening part 44 and the like are the same as in the configuration described referring to FIG. 3 above.

Besides, though not shown, a low-concentration region 33 may be formed over the first n-type region n1 and under the first p-type region p1, in the same manner as in the semiconductor device 15 described referring to FIG. 15 above.

In the semiconductor device 17, since the low-concentration region 34 is formed over the second p-type region p2 in the area where the second n-type region n2 is to be formed and the second n-type region n2 is formed over the low-concentration region 34, an electric field is moderated, withstand voltage performance is thereby enhanced, and an enhanced retention of the thyristor itself can be expected. Besides, the same effects as those of the semiconductor device 3 according to the third example above can be obtained. Furthermore, since the second n-type region n2 is formed over the low-concentration region 34, the cell area is not increased due to the formation of the low-concentration region 34.

In the next place, a modified example of the ninth example of one embodiment of the semiconductor device in the present invention will be described, referring to a schematic configuration sectional diagram shown in FIG. 18. This modified example is an example in which the epitaxial growth in the ninth example above is made in the inside of a hole.

The semiconductor device 18 has a configuration in which, in the semiconductor device 4 described referring to FIG. 4 above, a low-concentration region 34 is formed over the second p-type region p2 in the area where the second n-type region n2 is to be formed, and the second n-type region n2 is formed over the low-concentration region 34. The low-concentration region 34 is composed of a non-doped layer, a second conduction type (n-type) low-concentration region lower in dopant concentration than the second n-type region n2, or a first conduction type (p-type) low-concentration region lower in dopant concentration than the second p-type region p2. For example, in the case of the second conduction type (n-type) low-concentration region, it is formed to have a dopant concentration lower by about one or two orders than the dopant concentration in the second n-type region n2; in the case of the first conduction type (p-type) low-concentration region, it is formed to have a dopant concentration lower by about one or two orders than the dopant concentration in the second p-type region p2. In addition, the low-concentration region is formed in a film thickness of, for example, about 10 to 50 nm. Therefore, the semiconductor substrate 21, the gate insulating film 22, the gate electrode 23, the hard mask 24, the side walls 25, 26, the first insulating film 51, the opening 52, the second insulating film 53, the second insulating film 55 and the like are the same as in the configuration described referring to FIG. 4 above.

Besides, though not shown in the figure, a low-concentration region 33 may be formed over the first n-type region n1, in the same manner as in the semiconductor device 16 described referring to FIG. 16 above.

In the semiconductor device 18, since the low-concentration region 34 is formed over the second p-type region p2 in the area where the second n-type region n2 is to be formed and the second n-type region n2 is formed over the low-concentration region 34, an electric field is moderated, withstand voltage performance is thereby enhanced, and an enhanced retention of the thyristor itself can be expected. Besides, the same effects as those of the semiconductor device 4 according to the fourth example above can be obtained. Furthermore, since the low-concentration region 34 and the second n-type region n2 are self-alignedly formed in the inside of the opening part 53, the cell area is not increased due to the formation of the low-concentration region 34.

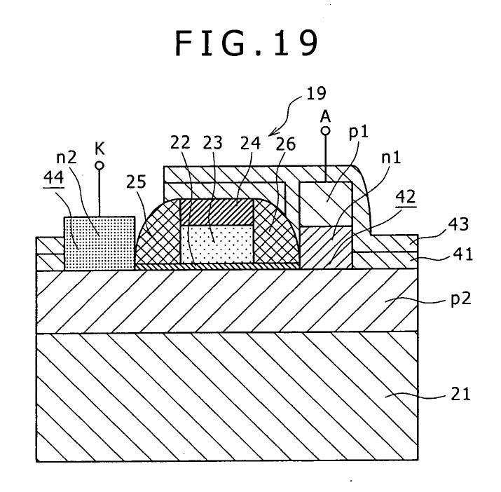

Now, a tenth example of one embodiment of the semiconductor device in the present invention will be described below, referring to a schematic configuration sectional diagram shown in FIG. 19. This tenth example is an example in which, in the first to ninth examples (inclusive of their modified examples) above, the second p-type region as the third region is formed over the semiconductor substrate 21. In FIG. 19, there is shown the case in which this tenth example is applied to the configuration described referring to FIG. 7 above.

As shown in FIG. 19, the semiconductor device 19 has a thyristor structure including a first region (hereinafter referred to as the first p-type region) p1 of a first conduction type (hereinafter referred to as p-type), a second region (hereinafter referred to as the first n-type region) n1 of a second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

A region of the first conduction type (p-type) is formed over a semiconductor substrate 21, and this region constitutes the second p-type region p2 of a thyristor. As the semiconductor substrate 21, for example, a silicon substrate is used. The second p-type region p2 is composed, for example, of an epitaxially grown silicon layer, and its film thickness is set in the range of 50 to 250 nm, for example. Besides, the epitaxially grown silicon layer is doped with boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

Furthermore, a first insulating film 41 is formed to cover the gate electrode 23, the hard mask 24, the side walls 25, 26 and the like. The first insulating film 41 is composed, for example, of a silicon nitride film in a thickness of, for example, 20 nm. In addition, the first insulating film 41 over the second p-type region p2 on one side (the right side in the figure) of the gate electrode 23, with the side wall 26 therebetween, is provided with an opening part 42. The first n-type region n1 of the second conduction type (n-type) which is in junction with the second p-type region p2 is formed in the opening part 42 over the second p-type region p2. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus.

Further, the first p-type region p1 of the first conduction type (p-type) is formed over the first n-type region n1. The first p-type region is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Furthermore, a second insulating film 43 is formed to cover the gate electrode 23, the hard mask 24, the side walls 25, 26, the first p-type region p1 and the like. The second insulating film 43 is composed, for example, of a silicon nitride film in a thickness of, for example, 20 nm. Besides, the first insulating film 41 and the second insulating film 43 over the second p-type region p2 on the other side (the left side in the figure) of the gate electrode 23, with the side wall 25 therebetween, are provided with an opening part 44.

The second n-type region n2 of the second conduction type (n-type) which is in junction with the second p-type region p2 is formed in the opening part 44 over the second p-type region p2. The second n-type region n2 is formed by implanting, for example, arsenic (As) as an n-type dopant in a dopant concentration of, for example, about 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic.

Furthermore, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

In the semiconductor device 19, since the second p-type region p2 is composed of the epitaxially grown silicon layer, the second p-type region p2 can be formed while accurately controlling the thickness of the second p-type region p2, the impurity concentration profile and the like, so that the thyristor characteristics such as holding current, holding voltage, ON/OFF speed, etc. of the semiconductor device 19 (thyristor) can be controlled easily. Therefore, it is easy to form a thyristor with desired characteristics. Further, since the thickness of the second p-type region p2 is reduced, the volume thereof can be reduced accordingly, whereby the operating speed of the thyristor is enhanced. Besides, since the thyristor portion is built upward from the semiconductor substrate 21, element isolation is facilitated, and the width of the element isolating region can be reduced, so that a reduction in the cell size can be achieved.

In addition, a reduction in the device size can be realized, since the first n-type region n1 and the first p-type region p1 are sequentially stackedly formed over a part of the second p-type region p2 and, further, the second n-type region n2 is stackedly formed over the second p-type region p2. Besides, since the first p-type region p1 and the first n-type region n1 are formed above the semiconductor substrate 21, it is possible to secure a margin in the thickness direction of the first n-type region n1 between the first p-type region p1 and the second p-type region p2, whereby punch-through resistance is enhanced advantageously. Further, the process margins are increased, and it is possible to secure wider windows of device characteristics. As a result, improvements in characteristics can be attained, and the semiconductor device 19 is a promising device even as one of the devices of the coming generations.

As has been described in connection with the tenth example above, the configuration in which the second p-type region p2 is composed of an epitaxially grown silicon layer over the semiconductor substrate 21 is applicable to any of the configurations described in the first to ninth examples (inclusive of their modified examples) above. In the cases where this configuration is applied to the configurations in the first to ninth examples (inclusive of their modified examples) above, also, the thyristor characteristics such as holding current, holding voltage, ON/OFF speed, etc. of the thyristor can be easily controlled, in the same manner as above-mentioned. Therefore, it is easy to form a thyristor with desired characteristics. Further, since the thickness of the second p-type region p2 is reduced, the volume thereof can be reduced, whereby the operating speed of the thyristor is enhanced. In addition, since the thyristor portion is built above the semiconductor substrate 21, element isolation can be achieved easily, and the width of the element isolating region can be reduced, so that a reduction in the cell size can be achieved.

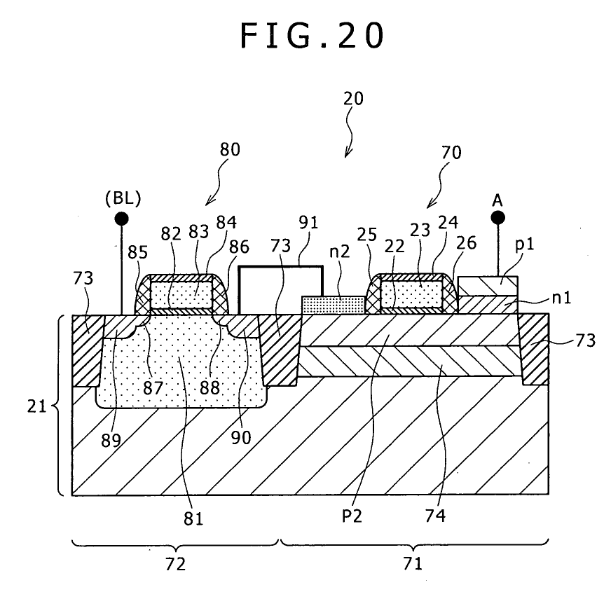

Now, an eleventh example of one embodiment of the semiconductor device in the present invention will be described below, referring to a schematic configuration sectional diagram shown in FIG. 20. The eleventh example is an example for illustrating the relationship between an element isolating region for demarcating a thyristor forming region and a selecting transistor forming region from each other and the second p-type region formed as the third region of the thyristor, and it is applicable in the above-described first to tenth examples (inclusive of their modified examples). In this eleventh example, the thyristor described referring to FIG. 7 above is used as an example.

As shown in FIG. 20, a semiconductor substrate 21 is provided with element isolating regions 73 each of which is for electrically isolating a thyristor forming region 71 and a selecting transistor forming region 72 from each other. The thyristor forming region 71 includes an n-type well region 74 of a second conduction type (hereinafter referred to as n-type) which is formed in the semiconductor substrate 21, and its junction position in the depth direction is located to be shallower than end portions in the depth direction of the element isolation regions 73. As the semiconductor substrate 21, for example, a silicon substrate is used.

The n-type well region 74 in the semiconductor substrate 21 has a thyristor structure including a first region (hereinafter referred to as the first p-type region) p1 of a first conduction type (hereinafter referred to as p-type), a second region (hereinafter referred to as the first n-type region) n1 of the second conduction type (hereinafter referred to as n-type) opposite to the first conduction type, a third region (hereinafter referred to as the second p-type region) p2 of the first conduction type (p-type), and a fourth region (hereinafter referred to as the second n-type region) n2 of the second conduction type (n-type), in sequential junction. The thyristor structure will be described in detail as follows.

The second p-type region p2 of the thyristor p2 is formed in the n-type well region 74 in the thyristor forming region 71 of the semiconductor substrate 21. The second p-type region p2 is composed, for example, of an ion-implanted layer. Besides, the second p-type region p2 is doped with boron (B) as a p-type dopant in a dopant concentration of about 5×10¹⁸ cm⁻³. The dopant concentration in the second p-type region p2 is desirably in the range of about 1×10¹⁸ to 1×10¹⁹ cm⁻³, and, basically, should be lower than the dopant concentration in the first n-type region n1 of the second conduction type (n-type) which will be described later. As the p-type dopant, p-type impurities such as indium (In) may be used, other than boron (B).

A gate electrode 23 is formed over the second p-type region p2, with a gate insulating film 22 therebetween. A hard mask 24 may be formed over the gate electrode 23. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are applicable to ordinary CMOS transistors can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

The gate electrode 23 is usually formed of polycrystalline silicon. Alternatively, a metal gate electrode may be used. Further, the gate electrode 23 may also be formed of silicon-germanium (SiGe) or the like. In addition, the hard mask 24 used in forming the gate electrode 23 may be left over the gate electrode 23. The hard mask 24 is composed, for example, of a silicon oxide (SiO₂) film, a silicon nitride (Si₃N₄) film or the like.

Side walls 25 and 26 are formed on side walls of the gate electrode 23. The side walls 25, 26 are each formed of silicon oxide (SiO₂), silicon nitride (Si₃N₄), or a laminate film of these materials.

The first n-type region n1 of the second conduction type (n-type) which is in junction with the second n-type region p1 is formed over the second p-type region p2 on one side (the right side in the figure) of the gate electrode 23, with the side wall therebetween. The first n-type region n1 is formed by implanting, for example, phosphorus (P) as an n-type dopant in a dopant concentration of, for example, 1.5×10¹⁹ cm⁻³. The dopant concentration is desirably in the range of about 1×10¹⁸ to 1×10²¹ cm^{,} and should be higher than the dopant concentration in the second p-type region p2. Other n-type dopants such as arsenic, antimony, etc. may be used, in place of phosphorus.

Further, the first p-type region p1 of the first conduction type (p-type) is formed over the first n-type region n1. The first p-type region p1 is formed, for example, by selective epitaxial growth in a film thickness of, for example, 200 nm and with a boron (B) concentration in film of, for example, 1×10²⁰ cm⁻³. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

In addition, the second n-type region n2 of the second conduction type (n-type) which is in junction with the second p-type region p2 is formed over the second p-type region p2 on the other side (the left side in the figure) of the gate electrode 23, with the side wall 25 therebetween. The second n-type region n2 is formed by implanting, for example, arsenic (As) as an n-type dopant in a dopant concentration of, for example, about 1×10¹⁹ cm⁻³. The dopant concentration is desirably in the range of about 1×10¹⁸ to 1×10²¹ cm⁻³; and should be higher than the dopant concentration in the second p-type region p2. Other n-type dopants such as phosphorus, antimony, etc. may be used, in place of arsenic.

Furthermore, an anode A is connected to the first p-type region p1, whereas a cathode K is connected to the second n-type region n2. In addition, though not shown, a silicide (titanium silicide, cobalt silicide, nickel silicide, or the like) may be formed over the first p-type region p1, the second n-type region n2 and the gate electrode 23.

On the other hand, the selecting transistor forming region 72 in the semiconductor substrate 21 is composed of a well region (hereinafter referred to as p-type well region 75) of the first conduction type (p-type), and a selecting transistor 80 is formed in the p-type well region 75. The selecting transistor 80 is composed, for example, of an n-channel transistor. In a specific example, a gate electrode 83 is formed over the semiconductor substrate 21, with a gate insulating film 82 therebetween. A hard mask 84 may be formed over the gate electrode 83. Side walls 85 and 86 are formed respectively on both sides of the gate electrode 83. The semiconductor substrate 21 is provided with extension regions 87 and 88 under the side walls 85 and 86, and source/drain regions 89 and 90 higher in dopant concentration than the extension regions 86 and 87 are formed in the semiconductor substrate 21 on both sides of the gate electrode 83, with the extension regions 87 and 88 therebetween. Besides, a channel is formed in the semiconductor substrate 21 between the extension regions 89 and 90.

The second n-type region n2 of the thyristor 70 (corresponding to the semiconductor device 7) and the source/drain region 90 on one side in the selecting transistor 80 are connected by a wire 91. In addition, the source/drain region 89 on the other side in the selecting transistor 80 is connected to a bit line (not shown) to be on the cathode side. Besides, the first p-type region p1 of the thyristor 70 is connected to the anode side.

In the semiconductor device 20 configured as described just above, the depth (junction depth) of the n-type well region 74 constituting the thyristor forming region 71 is set to be shallower than the depth of the end portions in the depth direction of the element isolating regions 73, so that element isolation can be achieved easily.

In the next place, a modified example of the thyristor according to the tenth example above will be described, referring to a schematic configuration sectional diagram shown in FIG. 21. A first n-type region n1, a first p-type region p1 and a second n-type region n2 in this modified example are applicable also to the first to ninth examples above.

As shown in FIG. 21, in the thyristor as above-described, a second p-type region p2 formed by epitaxial growth is selectively grown at an exposed portion of the n-type well region 74. Besides, in the case of selectively growing the first n-type region n1 over at least the second p-type region p2 on one side of the gate electrode 23, with the side wall 26 therebetween, it suffices to form a mask (not shown) so as to cover the second p-type region p2 on the other side of the gate electrode 23, with the side wall 25 therebetween. In this case, the first n-type region n1 is so formed as to cover the exposed portion of the second p-type region p2. Similarly, in the case of selectively growing the first p-type region p1 over the first n-type region n1, it suffices to form a mask (not shown) so as to cover at least the second p-type region p2 on the other side of the gate electrode 23, with the side wall 25 therebetween. As this mask, the mask having been used in forming the first n-type region n1 may be used again. In this case, the first p-type region p1 is so formed as to cover the exposed portion of the first n-type region n1.

Furthermore, in the case of selectively growing the second n-type region n2 over the second p-type region p2 on the other side of the gate electrode 23, with the side wall 25 therebetween, it suffices to form a mask (not shown) so as to cover at least the second p-type region p2 on the one side of the gate electrode 23, with the side wall 26 therebetween (so as to cover the first n-type region n1 and the first p-type region p1 in the case where these regions n1 and p1 have been formed). In this case, the second n-type region n2 is so formed as to cover the exposed portion of the second p-type region p2.

Even where the first n-type region n1, the first p-type region p1 and the second n-type region n2 are thus formed in a laminated manner, the same effects as described in the examples above can be obtained.

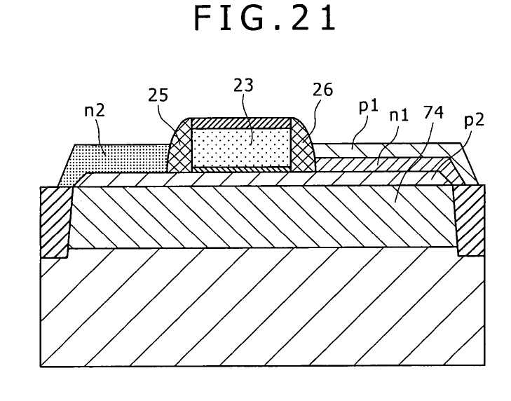

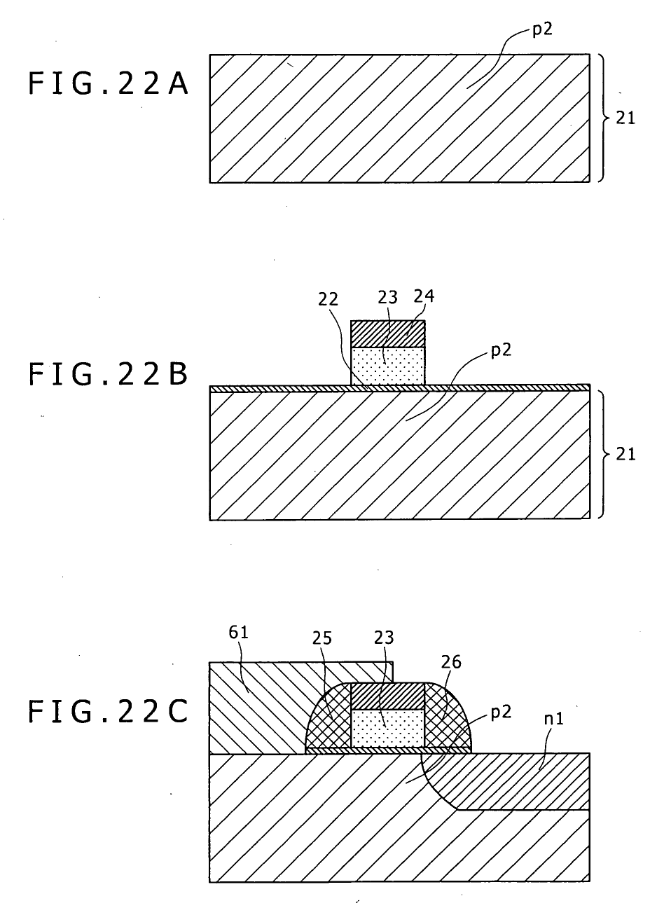

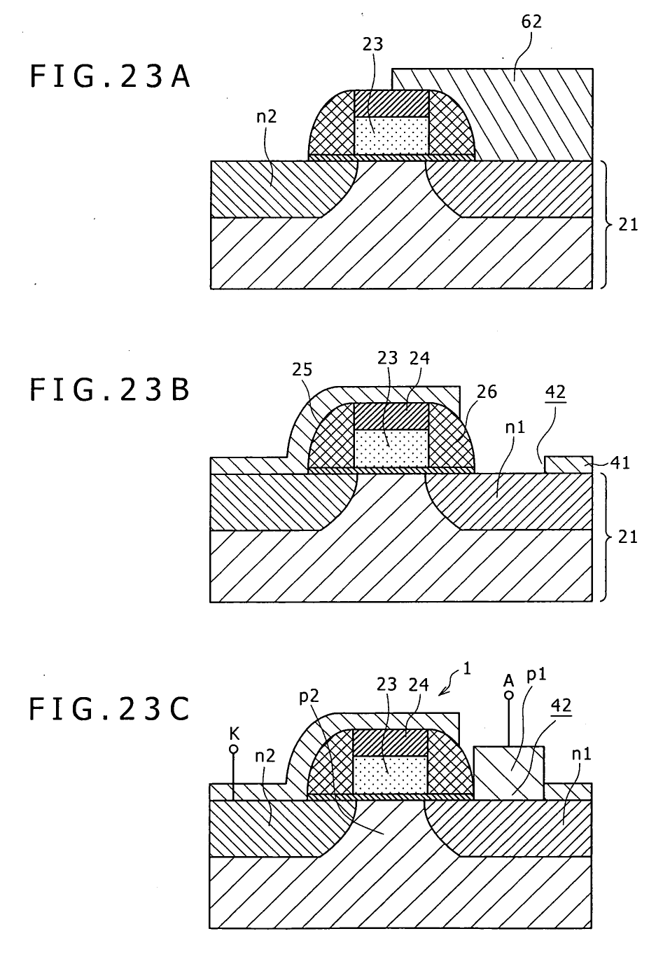

Now, a first example of one embodiment of the method of manufacturing a semiconductor device in the present invention will be described below, referring to the manufacturing step sectional diagrams shown in FIGS. 22A to 23C.

As shown in FIG. 22A, a silicon substrate, for example, is used as a semiconductor substrate 21. Element isolating regions (not shown) for isolating element forming regions from each other are formed in the semiconductor substrate 21, and thereafter an upper part of each element forming region in the semiconductor substrate 21 is formed into a region of a first conduction type (p-type). The p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻¹, and, basically, should be lower than the dopant concentration in a first n-type region of the second conduction type (n-type) which will be described later. As the p-type dopant, p-type impurities such as indium (In) may be used, other than boron (B).

Next, as shown in FIG. 22B, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film.

Next, as shown in FIG. 22C, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Subsequently, an ion-implanting mask 61 opened on one side (the right side in the figure) of the gate electrode 23, specifically, opened over the region where to form a first n-type region, is formed by ordinary resist application and lithography techniques. Next, an n-type dopant is implanted into the semiconductor substrate 21 on one side of the gate electrode 23 by an ion-implanting technique using the ion-implanting mask 61, to form the first n-type region n1. In one example of a set of ion-implanting conditions, phosphorus (P) is used as a dopant, and the dose is so set as to give a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus. Thereafter, the ion-implanting mask 61 is removed.

Next, as shown in FIG. 23A, an ion-implanting mask 62 opened on the other side (the left side in the figure) of the gate electrode 23, specifically, opened over the region where to form a second n-type region, is formed by ordinary resist application and lithography techniques. Subsequently, an n-type dopant is implanted into the semiconductor substrate 21 on the other side of the gate electrode 23 by an ion-implanting technique using the ion-implanting mask 62, to form the second n-type region n2. The second n-type region n2 is formed, for example, by selective epitaxial growth of silicon, with an arsenic (As) concentration in the silicon film set to 1×10²⁰ cm⁻³. In one example of a set of selective epitaxial growth conditions, an arsine (AsH₃) gas was used as a dopant gas, the substrate temperature at the time of forming the silicon epitaxial layer was set to, for example, 750° C., and the quantities of the raw material gases supplied, the pressure of the film forming atmosphere, etc. were so controlled to obtain a film thickness of 200 nm, for example. The dopant (arsenic) concentration is desirably in the range of about 1×10¹⁸ to 1×10²¹ cm⁻³. Other n-type impurities such as phosphine (PH₃) and organic sources may also be used as the dopant gas. Thereafter, the ion-implanting mask 62 is removed.

Subsequently, as shown in FIG. 23B, a first insulating film 41 is formed to cover the gate electrode 23, the hard mask 24, the side walls 25, 26 and the like. The first insulating film 41 is composed, for example, of a silicon nitride film in a thickness of, for example, 20 nm. Next, an etching mask (not shown) opened on one side (the right side in the figure) of the gate electrode 23, specifically, opened over at least a part of the first n-type region n1, is formed by ordinary resist application and lithography techniques. Thereafter, the first insulating film 41 over the first n-type region n1 is provided with an opening part 42 by etching using the etching mask. By this etching, the surface of the semiconductor substrate 21 only in a selective epitaxial growth area (the first n-type region n1) can be exposed. While the silicon nitride film was used as the first insulating film 41 as one example here, this film is for securing selectivity at the time of epitaxial growth and, therefore, other kinds of insulating films can also be used inasmuch as selectivity can be thereby maintained. Thereafter, the etching mask is removed.

Next, as shown in FIG. 23C, a first p-type region p1 of a first conduction type (p-type) is formed in the opening part 42 over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 10¹⁸ to 1×10²¹ cm⁻³. Besides, the film thickness is desirably in the range of about 50 to 300 nm, but it suffices for the thickness to be in such a range that the first p-type region p1 can function as an anode.

In addition, while the first n-type region n1 and the second n-type region n2 were formed in this order in the above-described example, they may be formed in the order of the second n-type region n2 and the first n-type region n1. Besides, in this case, cleaning of the surface of the silicon (Si) substrate by use of a chemical liquid such as hydrofluoric acid (HF) or hydrogen (H₂) gas or the like may be conducted, as required. Further, after the first n-type region n1 or the second n-type region n2 is formed, either one or both of the regions may be subjected to activating annealing, if necessary. As the activating annealing, for example, spike annealing at 1000° C. for 1 msec or less is conducted. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the first p-type region p1 and the second n-type region n2 at both end parts of the device, the first insulating film 41 and the second insulating film 43 over the regions are removed. In addition, before forming a layer insulating film (not shown), the hard mask 24 over the gate electrode 23 may be removed and a silicide (titanium silicide, cobalt silicide, nickel silicide or the like) may be formed by siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 1 as above (the first example of the manufacturing method), the first p-type region p1 is stackedly formed over the first n-type region n1, so that a reduction in device size can be achieved. In addition, since the first p-type region p1 is formed above the semiconductor substrate 21, it is possible to secure a margin in the thickness direction of the first n-type region n1 between the first p-type region p1 and the second p-type region p2, and punch-through resistance is enhanced advantageously. Further, the process margins are increased, and it is possible to secure wider windows of device characteristics. As a result, improvements of characteristics can be attained, and the manufacturing method can be applied to the manufacture of devices of the coming generations.

In the next place, a modified example of the first example of one embodiment of the method of manufacturing a semiconductor device in the present invention will be described. This modified example is an example in which the epitaxial growth in the first example of the manufacturing method is made in the inside of a hole.

To be more specific, in the method of manufacturing the second semiconductor device 2 described referring to FIG. 2, in the step of FIG. 23B illustrating the method of manufacturing the semiconductor device 1 as above-mentioned, a first insulating film 51 is formed to have a top surface higher than the gate electrode 23, and then the first insulating film 51 over the first n-type region n1 is provided with an opening part 52. Thereafter, a p-type region is epitaxially grown in the inside of the opening part 52 by an epitaxial growth method, to form a first p-type region p1 over the first n-type region. In this manner, the semiconductor device 2 described referring to FIG. 2 above can be manufactured.

In the method of manufacturing the semiconductor device 2 as described just above (the modified example of the first example of the manufacturing method), the first p-type region p1 is stackedly formed over the first n-type region n1, so that a reduction in device size can be achieved. In addition, since the first p-type region p1 is formed above the semiconductor substrate, it is possible to secure a margin in the thickness direction of the first n-type region between the first p-type region p1 and the second p-type region p2, so that punch-through resistance is enhanced advantageously. Further, the process margins are increased, and it is possible to secure wider windows of device characteristics. As a result, improvements of characteristics can be achieved, and this manufacturing method can be applied to the manufacture of the devices of the coming generations. Incidentally, in the description here, the component parts as those shown in FIG. 2 have been denoted by the same symbols as used in FIG. 2.

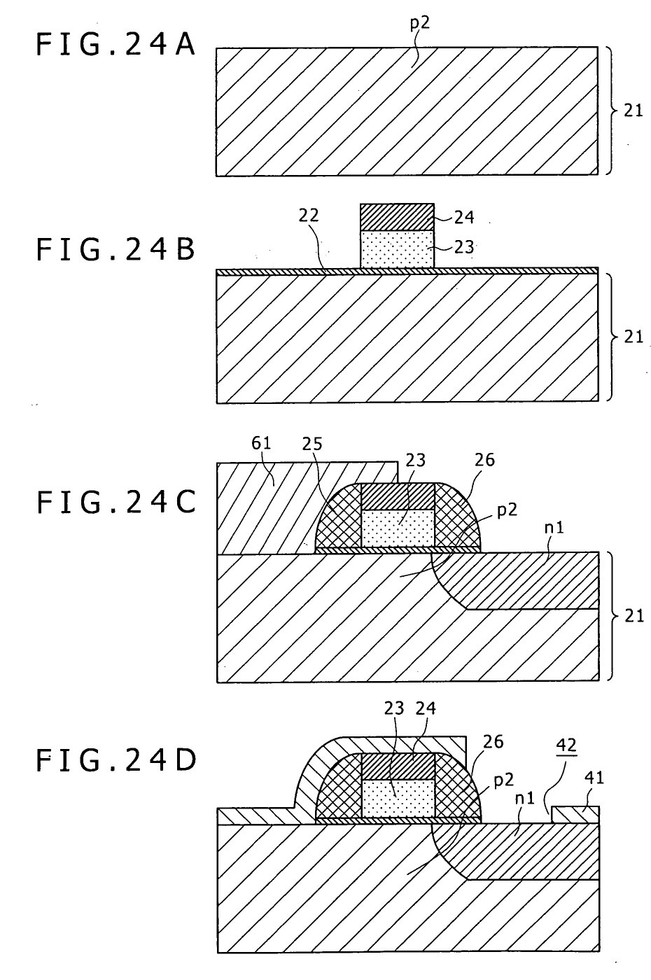

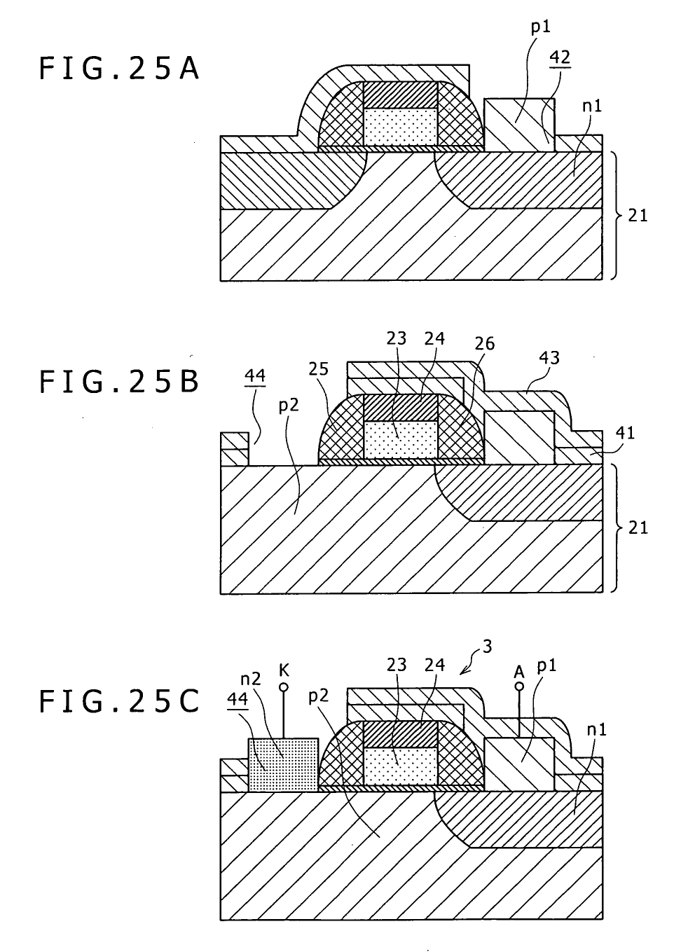

Now, a second example of one embodiment of the method of manufacturing a semiconductor device in the present invention will be described below, referring to manufacturing step sectional diagrams shown in FIGS. 24A to 25C.

As shown in FIG. 24A, a silicon substrate, for example, is used as a semiconductor substrate 21. Element isolating regions (not shown) for isolating element forming regions from each other are formed in the semiconductor substrate 21, and thereafter an upper part of each element forming region in the semiconductor substrate 21 is formed into a region of a first conduction type (p-type). The p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻³, and, basically, should be lower than the dopant concentration in a first n-type region of the second conduction type (n-type) which will be described later. As the p-type dopant, p-type impurities such as indium (In) may be used, other than boron (B).

Next, as shown in FIG. 24B, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film.

Next, as shown in FIG. 24C, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Subsequently, an ion-implanting mask 61 opened on one side (the right side in the figure) of the gate electrode 23, specifically, opened over the region where to form a first n-type region, is formed by ordinary resist application and lithography techniques. Next, an n-type dopant is implanted into the semiconductor substrate 21 on one side of the gate electrode 23 by an ion-implanting technique using the ion-implanting mask 61, to form the first n-type region n1. In one example of a set of ion-implanting conditions, phosphorus (P) is used as a dopant, and the dose is so set as to give a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus. Thereafter, the ion-implanting mask 61 is removed.

Subsequently, spike annealing at 1050° C. for 1 msec or less, for example, is conducted as activating annealing. It suffices for the annealing conditions in this case to be selected within such ranges that activation of the dopant can be achieved. Besides, the formation of the side walls 25, 26 may be carried out after the ion implantation for forming the first n-type region n1.

Next, as shown in FIG. 24D, a first insulating film 41 is formed to cover the gate electrode 23, the hard mask 24, the side walls 25, 26 and the like. The first insulating film 41 is composed, for example, of a silicon nitride film in a thickness of, for example, 20 nm. Subsequently, an etching mask (not shown) opened on one side (the right side in the figure) of the gate electrode 23, specifically, opened over at least a part of the first n-type region n1, is formed by ordinary resist application and lithography techniques. Thereafter, the first insulating film 41 over the first n-type region n1 is provided with an opening part 42 by etching using the etching mask. By this etching, the surface of the semiconductor substrate 21 only in a selective epitaxial growth area (the first n-type region n1) can be exposed. While the silicon nitride film was used as the first insulating film 41 as one example here, this film is for securing selectivity at the time of epitaxial growth and, therefore, other kinds of insulating films can also be used inasmuch as selectivity can be thereby maintained. Thereafter, the etching mask is removed.

Next, as shown in FIG. 25A, a first p-type region p1 of a first conduction type (p-type) is formed in the opening part 42 over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Besides, in this case, cleaning of the surface of the silicon (Si) substrate by use of a chemical liquid such as hydrofluoric acid (HF) or hydrogen (H₂) gas or the like may be conducted, as required.

Subsequently, as shown in FIG. 25B, a second insulating film 43 is formed to cover the gate electrode 23, the hard mask 24, the side walls 25, 26, the first insulating film 41 and the like. The second insulating film 43 is composed, for example, of a silicon nitride film in a thickness of, for example, 20 nm. Next, an etching mask (not shown) opened on the other side (the left side in the figure) of the gate electrode 23, specifically, opened over at least a part of the second p-type region p2, is formed by ordinary resist application and lithography techniques. Thereafter, the second insulating film 43 over the second p-type region p2 is provided with an opening part 44 by etching using the etching mask. By this etching, the surface of the semiconductor substrate 21 only in a selective epitaxial growth area (the second p-type region p2) can be exposed. While the silicon nitride film was used as the second insulating film 43 as one example here, this film is for securing selectivity at the time of epitaxial growth and, therefore, other kinds of insulating films can also be used inasmuch as selectivity can be thereby maintained. Thereafter, the etching mask is removed.

Next, as shown in FIG. 25C, a second n-type region n2 of a second conduction type (n-type) is formed in the inside of the opening part 44 over the second p-type region p2. The second n-type region n2 is formed, for example, by selective epitaxial growth of silicon, with an arsenic (As) concentration in the silicon film set to 1×10²⁰ cm³. In one example of a set of selective epitaxial growth conditions, an arsine (AsH₃) gas was used as a dopant gas, the substrate temperature at the time of forming the silicon epitaxial layer was set to, for example, 750° C., and the quantities of the raw material gases supplied, the pressure of the film-forming atmosphere, etc. were so controlled as to obtain a film thickness of 200 nm, for example. The dopant (arsenic) concentration is desirably in the range of about 1×10¹⁸ to 1×10²¹ cm⁻³. In addition, the film thickness is desirably in the range of about 50 to 300 nm, but it suffices for the thickness to be in such a range that the second n-type region n2 can function as a cathode. Besides, other n-type impurities such as phosphine (PH₃) and organic sources may also be used as the dopant gas.

In addition, while the first p-type region p1 and the second n-type region n2 were formed in this order in the above-described example, they may be formed in the order of the second n-type region n2 and the first p-type region p1. Besides, in this case, cleaning of the surface of the silicon (Si) substrate by use of a chemical liquid such as hydrofluoric acid (HF) or hydrogen (H₂) gas or the like may be conducted, as required. Further, after the first p-type region p1 or the second n-type region n2 is formed, either one or both of the regions may be subjected to activating annealing, if necessary. As the activating annealing, for example, spike annealing at 1000° C. for 1 msec or less is conducted. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the first p-type region p1 and the second n-type region n2 at both end parts of the device, the first insulating film 41 and the second insulating film 43 over the regions are removed. In addition, before forming a layer insulating film (not shown), the hard mask 24 over the gate electrode 23 may be removed and a silicide (titanium silicide, cobalt silicide, nickel silicide or the like) may be formed by siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 3 as described just above (the second example of the manufacturing method), the first p-type region p1 is stackedly formed over the first n-type region n1 and, further, the second n-type region n2 is stackedly formed over the second p-type region p2, so that a reduction in device size can be achieved. In addition, since the first p-type region p1 is formed above the semiconductor substrate 21, it is possible to secure a margin in the thickness direction of the first n-type region n1 between the first p-type region p1 and the second p-type region p2, so that punch-through resistance is enhanced advantageously. Further, the process margins are increased, and it is possible to secure wider windows of device characteristics. As a result, improvements of characteristics can be achieved, and this manufacturing method can be applied to the manufacture of the devices of the coming generations.

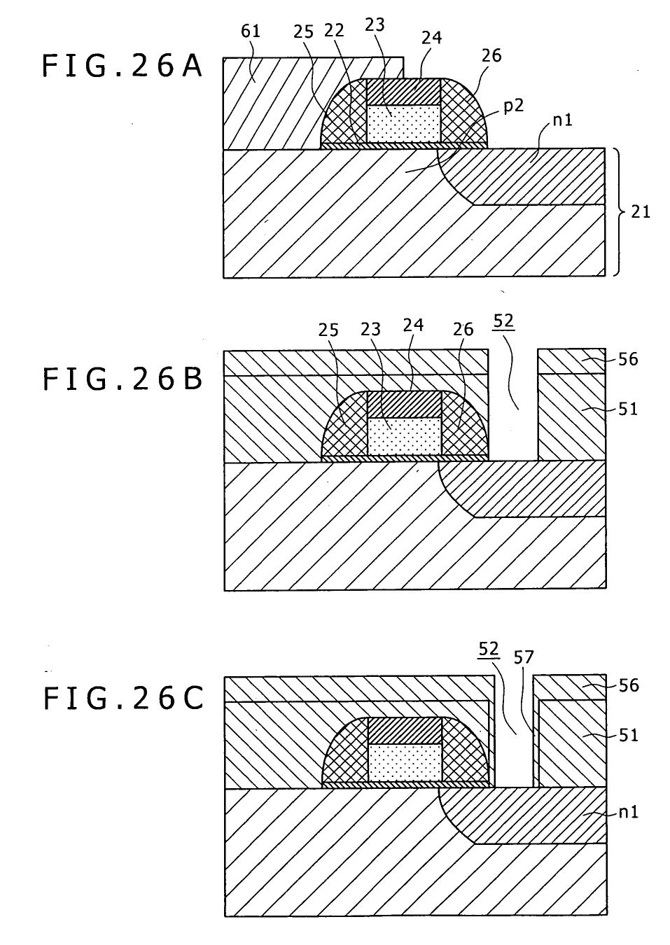

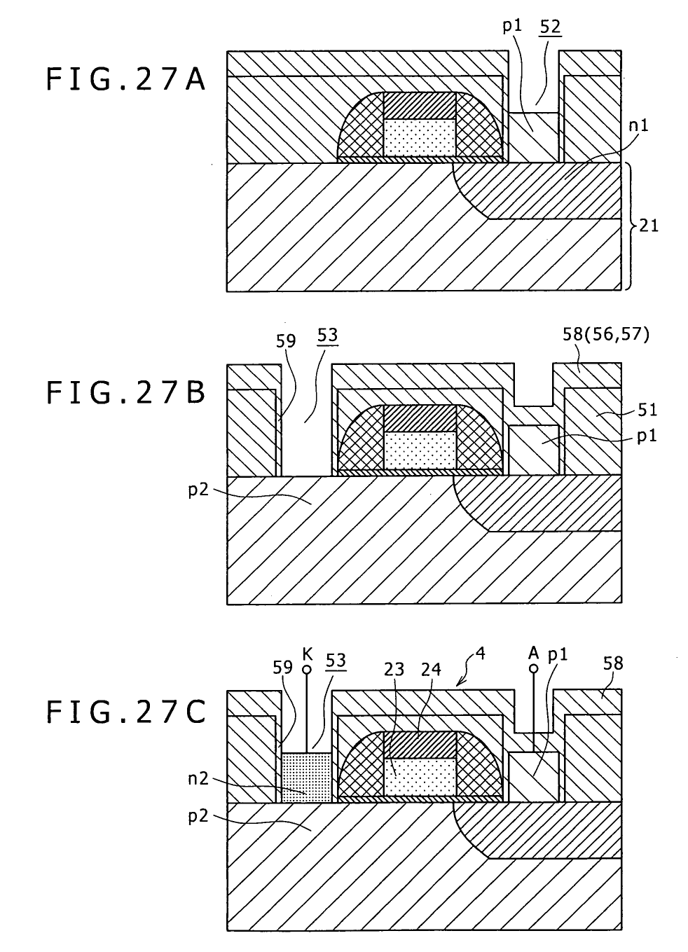

In the next place, a modified example of the second example of one embodiment of the method of manufacturing a semiconductor device in the present invention will be described, referring to manufacturing step sectional diagrams shown in FIGS. 26A to 27C. This modified example is an example in which the epitaxial growth in the second example of the manufacturing method above is made in the inside of a hole.

As shown in FIG. 26A, in the same manner as in the description made referring to FIGS. 24A to 24C, a silicon substrate, for example, is used as a semiconductor substrate 21, element isolating regions (not shown) for isolating element forming regions from each other are formed in the semiconductor substrate 21, and an upper part of each element forming regions in the semiconductor substrate 21 is formed into a region of a first conduction type (p-type). This p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻³, and, basically, should be lower than the dopant concentration in a first n-type region of a second conduction type (n-type) which will be described later. As the p-type dopant, p-type impurities such as indium (In) may be used, other than boron (B).

Next, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film.

Next, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Subsequently, an ion-implanting mask 61 opened on one side (the right side in the figure) of the gate electrode 23, specifically, opened over the region where to form a first n-type region, is formed by ordinary resist application and lithography techniques. Next, an n-type dopant is implanted into the semiconductor substrate 21 on one side of the gate electrode 23 by an ion-implanting technique using the ion-implanting mask 61, to form the first n-type region n1. In one example of a set of ion-implanting conditions, phosphorus (P) is used as a dopant, and the dose is so set as to give a dopant concentration of, for example, 1.5×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as arsenic, antimony, etc. may be used, in place of phosphorus. Thereafter, the ion-implanting mask 61 is removed.

Subsequently, spike annealing at 1050° C. for 1 msec or less, for example, is conducted as activating annealing. It suffices for the annealing conditions in this case to be selected within such ranges that activation of the dopant can be achieved. Besides, the formation of the side walls 25, 26 may be carried out after the ion implantation for forming the first n-type region n1.

Next, as shown in FIG. 26B, a first insulating film 51 is formed to cover the gate electrode 23, the hard mask 24, the side walls 25, 26 and the like. The first insulating film 51 is formed, for example, by depositing silicon oxide formed by a high-density plasma CVD method (HDP-SiO₂) in a thickness of 500 nm. Further, a second insulating film 56 is formed. The second insulating film 56 is formed, for example, by depositing a silicon nitride film in a thickness of 50 nm.

Subsequently, an etching mask (not shown) opened on one side (the right side in the figure) of the gate electrode 23, specifically, opened over the first n-type region n1 in the area where to form a first p-type region, is formed by ordinary resist application and lithography techniques. Followingly, the second insulating film 56 and the first insulating film 51 on one side (the right side in the figure) of the gate electrode 23 are provided with an opening part 52 by etching using the etching mask.

Next, as shown in FIG. 26C, a third insulating film 57 is formed so as to cover the second insulating film 56 and the inside surfaces of the opening part 52. The third insulating film 57 is formed, for example, by depositing a silicon nitride film in a thickness of 20 nm. Thereafter, the third insulating film 57 is etched, to expose the first n-type region n1 at a bottom portion of the opening part 52. By this it is possible to expose the surface of the silicon (Si) substrate only in the area of selective epitaxial growth. In the etching step, the third insulating film 57 over the surface of the second insulating film 56 is also removed. While the second insulating film 56 and the third insulating film 57 each composed of a silicon nitride film were formed as an example here, these insulating films are for securing selectivity at the time of epitaxial growth and, therefore, other kinds of insulating films can also be used inasmuch as selectivity can be thereby maintained. In addition, the second insulating film 56 and the third insulating film 57 may be omitted if the selective growth in epitaxial growth can be achieved by the presence of the first insulating film 51 alone.

Subsequently, as shown in FIG. 27A, a first p-type region p1 of a first conduction type (p-type) is formed in the opening part 42 over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 10¹⁸ to 1×10²¹ cm⁻³. Besides, the film thickness is desirably in the range of about 50 to 300 nm, but it suffices for the thickness to be in such a range that the first p-type region p1 can function as an anode.

Besides, in this case, cleaning of the surface of the semiconductor substrate 21 by use of a chemical liquid such as hydrofluoric acid (HF) or hydrogen (H₂) gas or the like may be conducted, as required.

Next, as shown in FIG. 27B, a fourth insulating film 58 is formed so as to cover the whole surface on the side where the first p-type region p1 is formed. The fourth insulating film 58 is formed, for example, by depositing a silicon nitride film in a thickness of 20 nm. Then, an etching mask (not shown) opened on the other side (the left side in the figure) of the gate electrode 23, specifically, opened over the second p-type region p2 in the area where to form a second n-type region, is formed by ordinary resist application and lithography techniques. Subsequently, the insulating films ranging from the fourth insulating film 58 to the first insulating film 51 on the other side (the left side in the figure) of the gate electrode 23 are provided with an opening part 53 by an etching technique using the etching mask. Thereafter, the etching mask is removed. Next, a fifth insulating film 59 is formed over the fourth insulating film 58 and the inside surfaces of the opening part 53. The fifth insulating film 59 is formed, for example, by depositing a silicon nitride film in a thickness of 20 nm. Thereafter, the fifth insulating film 59 is etched, to expose the second p-type region p2 at a bottom portion of the opening part 53. By this it is possible to expose the surface of the silicon (Si) substrate only in the area of selective epitaxial growth. In this etching step, the fifth insulating film 59 over the fourth insulating film 58 is also removed. While the fourth insulating film 58 and the fifth insulating film 59 each composed of the silicon nitride film were formed as an example here, these insulating films are for securing selectivity at the time of epitaxial growth and, therefore, other kinds of insulating films and other film thicknesses may also be adopted insofar as the selectivity can be thereby achieved. In addition, the fourth insulating film 58 and the fifth insulating film 59 may be omitted together with the second insulating film 56 and the third insulating film 57 if selectivity in epitaxial growth can be secured by the presence of the first insulating film 51 alone.

Subsequently, as shown in FIG. 27C, a second n-type region n2 of a second conduction type (n-type) is formed in the inside of the opening part 53 over the second p-type region p2. The second n-type region n2 is formed, for example, by selective epitaxial growth, with an arsenic (As) concentration in film set to 1×10²⁰ cm⁻³. In one example of a set of selective epitaxial growth conditions, a diborane (B₂H₆) gas was used as a dopant gas, the substrate temperature at the time of film formation was set to, for example, 750° C., and the quantities of the raw material gases supplied, the pressure of the film-forming atmosphere, etc. were so controlled as to obtain a film thickness of 200 nm, for example. The dopant (arsenic) concentration is desirably in the range of about 1×10¹⁸ to 1×10²¹ cm⁻³. In addition, the film thickness is desirably in the range of about 50 to 300 nm, but it suffices for the thickness to be in such a range that the second n-type region n2 can function as a cathode. Besides, an arsine (AsH₃) gas may be used as the dopant gas; further, phosphine (PH₃), organic sources containing an n-type impurity, and the like may be used as the dopant gas.

In addition, while the first p-type region p1 and the second n-type region n2 were formed in this order in the just-described example, they may be formed in the order of the second n-type region n2 and the first p-type region p1. Besides, in this case, cleaning of the surface of the silicon (Si) substrate by use of a chemical liquid such as hydrofluoric acid (HF) or hydrogen (H₂) gas or the like may be conducted, as required. Further, after the first p-type region p1 or the second n-type region n2 is formed, either one or both of the regions may be subjected to activating annealing, if necessary. As the activating annealing, for example, spike annealing at 1000° C. for 1 msec or less is conducted. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the first p-type region p1, the fourth insulating film 58 and the fifth insulating film 59 over the regions are removed. In addition, before forming a layer insulating film (not shown), the hard mask 24 and the insulating films over the gate electrode 23 may be removed and a silicide (titanium silicide, cobalt silicide, nickel silicide or the like) may be formed by siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 4 as just-described (the modified example of the second example of the manufacturing method), the first p-type region p1 is self-alignedly stacked in the opening part 52 over the first n-type region n1 and, further, the second n-type region n2 is self-alignedly stacked in the opening part 53 over the second p-type region, so that a further reduction in device size can be realized, as compared with the method of manufacturing the semiconductor device 3 as above-described (the second example of the manufacturing method). In addition, since the first p-type region p1 is formed above the semiconductor substrate 21, it is possible to secure a margin in the thickness direction of the first n-type region n1 between the first p-type region p1 and the second p-type region p2, and punch-through resistance is enhanced advantageously. Further, the process margins are increased, and it is possible to secure wider windows of device characteristics. As a result, improvements in characteristics can be attained, and this manufacturing method can be applied to the manufacture of the devices of the coming generations.

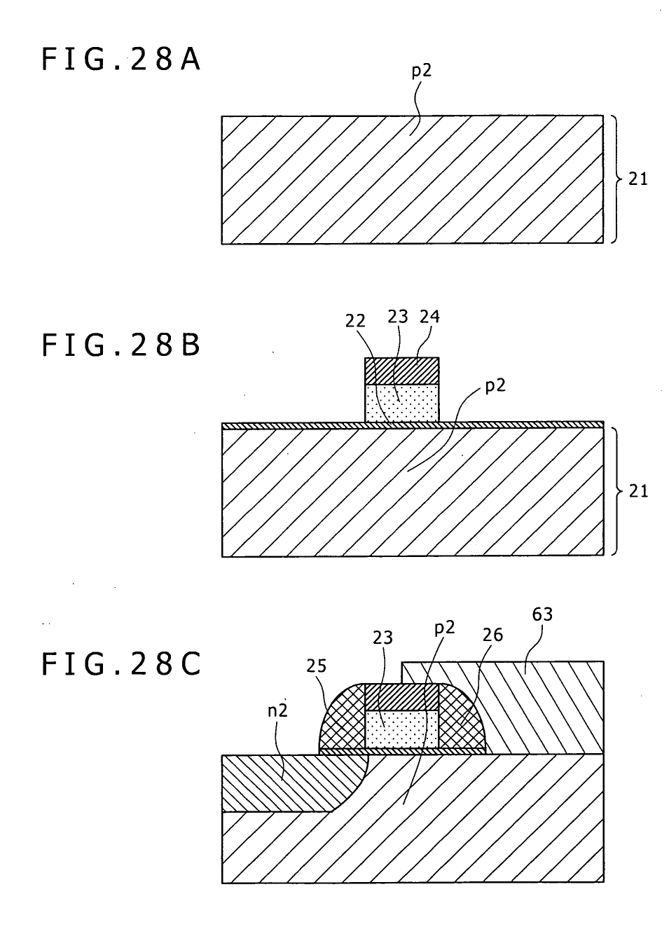

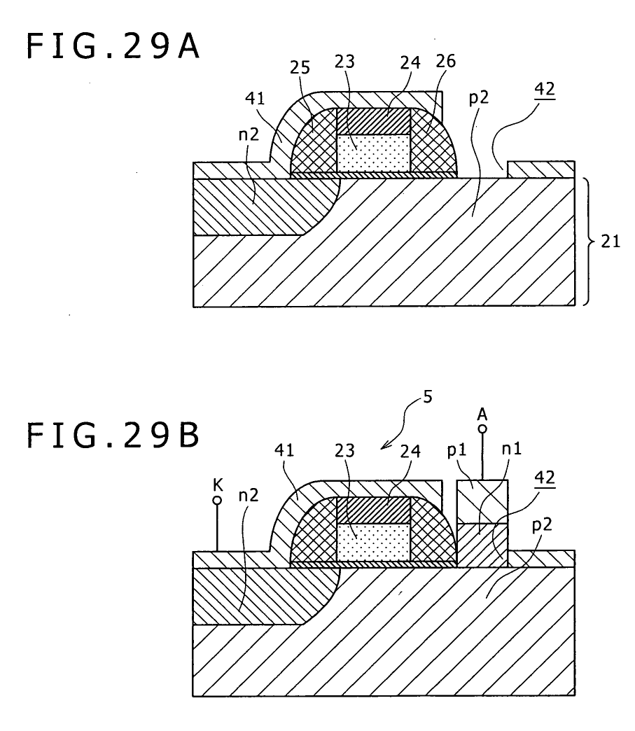

Now, a third example of one embodiment of the method of manufacturing a semiconductor device in the present invention will be described below, referring to manufacturing step sectional diagrams shown in FIGS. 28A to 29B. This is an example of the method of manufacturing the semiconductor device 5 described referring to FIG. 5 above.

As shown in FIG. 28A, a silicon substrate, for example, is used as a semiconductor substrate 21. Element isolating regions (not shown) for isolating element forming regions from each other are formed in the semiconductor substrate 21, and thereafter an upper part of each element forming region in the semiconductor substrate 21 is formed into a region of a first conduction type (p-type). The p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻³, and, basically, should be lower than the dopant concentration in a first n-type region of the second conduction type (n-type) which will be described later. As the p-type dopant, p-type impurities such as indium (In) may be used, other than boron (B).

Next, as shown in FIG. 28B, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film.

Next, as shown in FIG. 28C, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Subsequently, an ion-implanting mask 63 opened on one side (the left side in the figure) of the gate electrode 23, specifically, opened over the region where to form a second n-type region, is formed by ordinary resist application and lithography techniques. Next, an n-type dopant is implanted into the semiconductor substrate 21 on one side of the gate electrode 23 by an ion-implanting technique using the ion-implanting mask 63, to form the second n-type region n2. In one example of a set of ion-implanting conditions, arsenic (As) is used as a dopant, and the dose is so set as to give a dopant concentration of, for example, 1×10¹⁹ cm⁻³. The dopant concentration is desirably in the range of about 1×10¹⁸ to 1×10²¹ cm⁻³, and should be higher than the dopant concentration in the second p-type region p2. Other n-type dopants such as phosphorus, antimony, etc. may be used, in place of arsenic. Thereafter, the ion-implanting mask 63 is removed.

Subsequently, spike annealing at 1050° C. for 1 msec or less, for example, is conducted as activating annealing. It suffices for the annealing conditions in this case to be selected within such ranges that activation of the dopant can be achieved. Besides, the formation of the side walls 25, 26 may be carried out after the ion implantation for forming the second n-type region n2.

Next, as shown in FIG. 29A, a first insulating film 41 is formed to cover the gate electrode 23, the hard mask 24, the side walls 25, 26 and the like. The first insulating film 41 is composed, for example, of a silicon nitride film in a thickness of, for example, 20 nm. Subsequently, an etching mask (not shown) opened on the other side (the right side in the figure) of the gate electrode 23, specifically, opened over at least a part of the second p-type region p2, is formed by ordinary resist application and lithography techniques. Thereafter, the first insulating film 41 over the second p-type region p2 is provided with an opening part 42 by etching using the etching mask. By this etching, the surface of the semiconductor substrate 21 only in a selective epitaxial growth area (the second p-type region p2) can be exposed. While the silicon nitride film was used as the first insulating film 41 as one example here, this film is for securing selectivity at the time of epitaxial growth and, therefore, other kinds of insulating films can also be used inasmuch as selectivity can be thereby maintained. Furthermore, this step can also be conducted simultaneously with the formation of the side walls.

Subsequently, as shown in FIG. 29B, a first n-type region n1 of a second conduction type (n-type) is formed in the inside of the opening part 42 over the second p-type region p2. In this case, cleaning of the surface of the silicon (Si) substrate by use of a chemical liquid such as hydrofluoric acid (HF) and hydrogen (H₂) gas may be conducted, as required. The first n-type region n1 is formed, for example, by selective epitaxial growth, with a phosphorus (P) concentration in film set to 1.5×10²⁰ cm⁻³. In one example of a set of selective epitaxial growth conditions, a diborane (B₂H₆) gas was used as a dopant gas, the substrate temperature at the time of film formation was set to, for example, 750° C., and the quantities of the raw material gases supplied, the pressure of the film-forming atmosphere, etc. were so controlled as to obtain a film thickness of 100 nm, for example. The dopant (arsenic) concentration is desirably in the range of about 1×10¹⁸ to 1×10²¹ cm⁻³. In addition, the film thickness is desirably in the range of about 50 to 300 nm. Besides, an arsine (AsH₃) gas may be used as the dopant gas; further, phosphine (PH₃), organic sources containing an n-type impurity, and the like may be used as the dopant gas.

Furthermore, in succession to the just-mentioned epitaxial growth, a first p-type region p1 of a first conduction type (p-type) is formed over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

In addition, after the first p-type region p1 is formed, activating annealing may be conducted, if necessary. As the activating annealing, for example, spike annealing at 1000° C. for 1 msec or less is carried out. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the second n-type region n2, the first insulating film 41 is removed. In addition, before forming a layer insulating film (not shown), the hard mask 24 and the first insulating film 41 and the like over the gate electrode 23 may be removed and a silicide (titanium silicide, cobalt silicide, nickel silicide or the like) may be formed by a siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 5 as described just above (the third example of the manufacturing method), the first n-type region n1 is formed over a part of the second p-type region p2 and, further, the first p-type region p1 is stackedly formed over the first n-type region n1, so that a reduction in device size can be achieved. In addition, since the first p-type region p1 and the first n-type region n1 are formed above the semiconductor substrate 21, it is possible to secure a margin in the thickness direction of the first n-type region n1 between the first p-type region p1 and the second p-type region p2, so that punch-through resistance is enhanced advantageously. Further, the process margins are increased, and it is possible to secure wider windows of device characteristics. As a result, improvements of characteristics can be achieved, and this manufacturing method can be applied to the manufacture of the devices of the coming generations.

In the next place, a modified example of the third example of one embodiment of the method of manufacturing a semiconductor device in the present invention will be described below. This modified example is an example in which the epitaxial growth in the third example of the manufacturing method above is made in the inside of a hole.

The method of manufacturing the semiconductor device 6 described referring to FIG. 6 above is a method in which, in the step of FIG. 29A illustrating the method of manufacturing the semiconductor device 5, the first insulating film 51 is formed to have a height above the height of the gate electrode 23, and then the opening part 52 is formed in the first insulating film 51 over the second p-type region p2 on the side opposite to the side where the second n-type region n2 is formed, with respect to the gate electrode 23. Thereafter, an n-type region is epitaxially grown in the inside of the opening part 52 by an epitaxial growth method, to form the first n-type region n1 over the second p-type region p2, and then a p-type region is epitaxially grown over the first n-type region n1, to form the first p-type region p1 over the first n-type region n1. In this manner, the semiconductor device 6 described referring to FIG. 6 above can be formed.

In the method of manufacturing the semiconductor device 6 as described just above (the modified example of the third example of the manufacturing method), the first n-type region n1 is stackedly formed over the second p-type region p2 and, further, the first p-type region p1 is stackedly formed over the first n-type region n1, so that a reduction in device size can be achieved. In addition, since the first p-type region p1 and the first n-type region n1 are formed above the semiconductor substrate 21, it is possible to secure a margin in the thickness direction of the first n-type region n1 between the first p-type region p1 and the second p-type region p2, so that punch-through resistance is enhanced advantageously. Further, the process margins are increased, and it is possible to secure wider windows of device characteristics. As a result, improvements of characteristics can be achieved, and this manufacturing method can be applied to the manufacture of the devices of the coming generations. Incidentally, the same component parts as those shown in FIG. 6 have been denoted by the same symbols as used in FIG. 6.

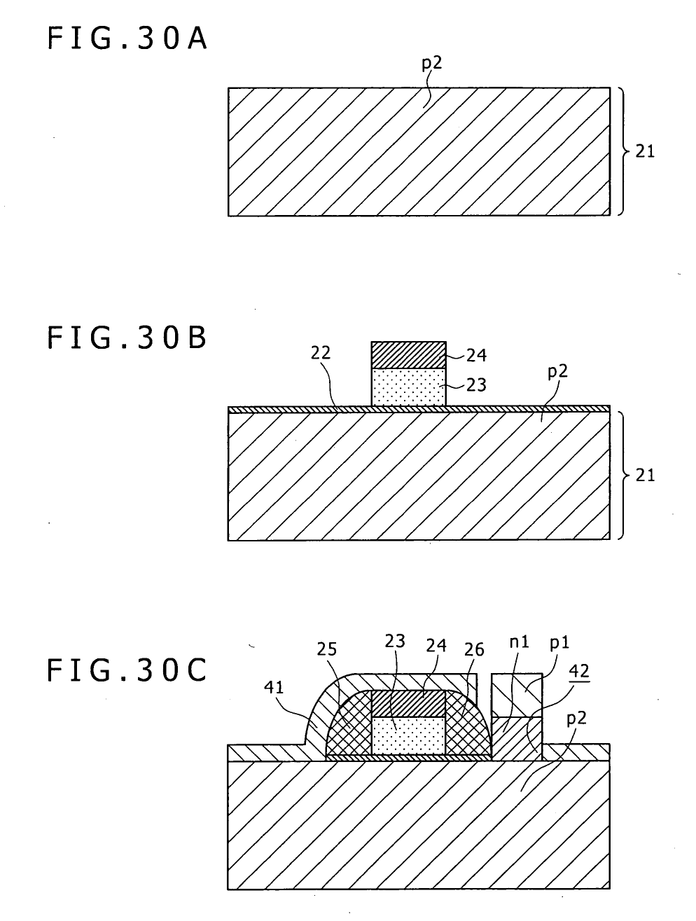

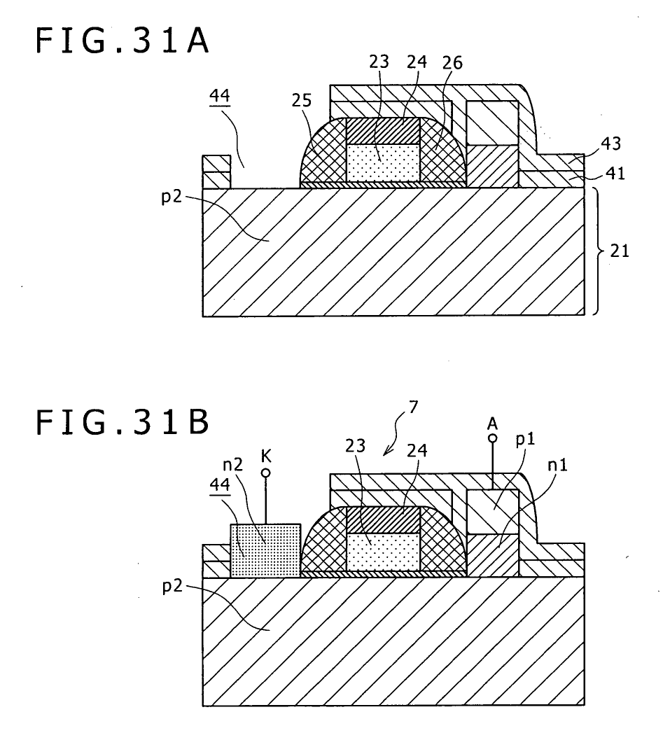

Now, a fourth example of one embodiment of the method of manufacturing a semiconductor device in the present invention will be described below, referring to manufacturing step sectional diagrams shown in FIGS. 30A to 31B. This is an example of the method of manufacturing the semiconductor device 7 shown in FIG. 7 above.

As shown in FIG. 30A, a silicon substrate, for example, is used as a semiconductor substrate 21. Element isolating regions (not shown) for isolating element forming regions from each other are formed in the semiconductor substrate 21, and thereafter an upper part of each element forming region in the semiconductor substrate 21 is formed into a region of a first conduction type (p-type). The p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻³, and, basically, should be lower than the dopant concentration in a first n-type region of the second conduction type (n-type) which will be described later. As the p-type dopant, p-type impurities such as indium (In) may be used, other than boron (B).

Next, as shown in FIG. 30B, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film. Thereafter, the etching mask is removed.

Next, as shown in FIG. 30C, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Next, a first insulating film 41 is formed to cover the gate electrode 23, the hard mask 24, the side walls 25, 26 and the like. The first insulating film 41 is composed, for example, of a silicon nitride film in a thickness of, for example, 20 nm. Subsequently, an etching mask (not shown) opened on one side (the right side in the figure) of the gate electrode 23, specifically, opened over at least a part of the second p-type region p2, is formed by ordinary resist application and lithography techniques. Thereafter, the first insulating film 41 over the second p-type region p2 is provided with an opening part 42 by etching using the etching mask. By this etching, the surface of the semiconductor substrate 21 only in a selective epitaxial growth area (the second p-type region p2) can be exposed. While the silicon nitride film was used as the first insulating film 41 as one example here, this film is for securing selectivity at the time of epitaxial growth and, therefore, other kinds of insulating films can also be used inasmuch as selectivity can be thereby maintained. Furthermore, this step can also be conducted simultaneously with the formation of the side walls. Thereafter, the etching mask is removed.

Subsequently, a first n-type region n1 of a second conduction type (n-type) is formed in the inside of the opening part 42 over the second p-type region p2. In this case, cleaning of the surface of the silicon (Si) substrate by use of a chemical liquid such as hydrofluoric acid (HF) and hydrogen (H₂) gas may be conducted, as required. The first n-type region n1 is formed, for example, by selective epitaxial growth, with a phosphorus (P) concentration in film set to 1.5×10²⁰ cm⁻³. In one example of a set of selective epitaxial growth conditions, a diborane (B₂H₆) gas was used as a dopant gas, the substrate temperature at the time of film formation was set to, for example, 750° C., and the quantities of the raw material gases supplied, the pressure of the film-forming atmosphere, etc. were so controlled as to obtain a film thickness of 100 nm, for example. The dopant (arsenic) concentration is desirably in the range of about 1×10¹⁸ to 1×10²¹ cm⁻³. In addition, the film thickness is desirably in the range of about 50 to 300 nm. Besides, an arsine (AsH₃) gas may also be used as the dopant gas; further, phosphine (PH₃), organic sources containing an n-type impurity, and the like may be used as the dopant gas.

Furthermore, in succession to the just-mentioned epitaxial growth, a first p-type region p1 of a first conduction type (p-type) is formed over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Subsequently, as shown in FIG. 31A, a second insulating film 43 is formed to cover the gate electrode 23, the hard mask 24, the side walls 25, 26, the first insulating film 41 and the like. The second insulating film 43 is composed, for example, of a silicon nitride film in a thickness of, for example, 20 nm. Next, an etching mask (not shown) opened on the other side of the gate electrode 23, specifically, opened over at least a part of the second p-type region p2, is formed by ordinary resist application and lithography techniques. Thereafter, the second insulating film 43 and the first insulating film 41 over the second p-type region p2 are provided with an opening part 44 by etching using the etching mask. By this etching, the surface of the semiconductor substrate 21 only in a selective epitaxial growth area (the second p-type region p2) can be exposed. While the silicon nitride film was used as the second insulating film 43 as one example here, this film is for securing selectivity at the time of epitaxial growth and, therefore, other kinds of insulating films can also be used inasmuch as selectivity can be thereby maintained. Thereafter, the etching mask is removed.

Next, as shown in FIG. 31B, a second n-type region n2 of the second conduction type (n-type) is formed in the inside of the opening part 44 over the second p-type region p2. The second n-type region n2 is formed, for example, by selective epitaxial growth of silicon, with an arsenic (As) concentration in the silicon film set to 1×10²⁰ cm⁻³. In one example of a set of selective epitaxial growth conditions, an arsine (AsH₃) gas was used as a dopant gas, the substrate temperature at the time of forming the silicon epitaxial layer was set to, for example, 750° C., and the quantities of the raw material gases supplied, the pressure of the film-forming atmosphere, etc. were so controlled as to obtain a film thickness of 200 nm, for example. The dopant (arsenic) concentration is desirably in the range of about 1×10¹⁸ to 1×10²¹ cm⁻³. In addition, the film thickness is desirably in the range of about 50 to 300 nm, but it suffices for the thickness to be in such a range that the second n-type region n2 can function as a cathode. Besides, other n-type impurities such as phosphine (PH₃) and organic sources may also be used as the dopant gas.

In addition, while the first n-type region n1, the first p-type region p1 and the second n-type region n2 were formed in this order in the just-described example, the second n-type region n2 may be formed before the first n-type region n1 and the first p-type region p1 are formed. Besides, in this case, cleaning of the surface of the silicon (Si) substrate by use of a chemical liquid such as hydrofluoric acid (HF) or hydrogen (H₂) gas or the like may be conducted, as required. Further, after the first p-type region p1 or the second n-type region n2 is formed, either one or both of the regions may be subjected to activating annealing, if necessary. As the activating annealing, for example, spike annealing at 1000° C. for 1 msec or less is conducted. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the first p-type region p1 and the second n-type region n2, the first insulating film 41 and the second insulating film 43 over the regions are removed. In addition, before forming a layer insulating film (not shown), the hard mask 24 over the gate electrode 23 may be removed and a silicide (titanium silicide, cobalt silicide, nickel silicide or the like) may be formed by siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 7 as described just above (the fourth example of the manufacturing method), the first n-type region n1 and the first p-type region p1 are sequentially stackedly formed over the second p-type region p2 and, further, the second n-type region n2 is stackedly formed over the second p-type region p2, so that a reduction in device size can be achieved. In addition, since the first p-type region p1 and the first n-type region n1 are formed above the semiconductor substrate 21, it is possible to secure a margin in the thickness direction of the first n-type region n1 between the first p-type region p1 and the second p-type region p2, so that punch-through resistance is enhanced advantageously. Further, the process margins are increased, and it is possible to secure wider windows of device characteristics. As a result, improvements of characteristics can be achieved, and this manufacturing method can be applied to the manufacture of the devices of the coming generations.

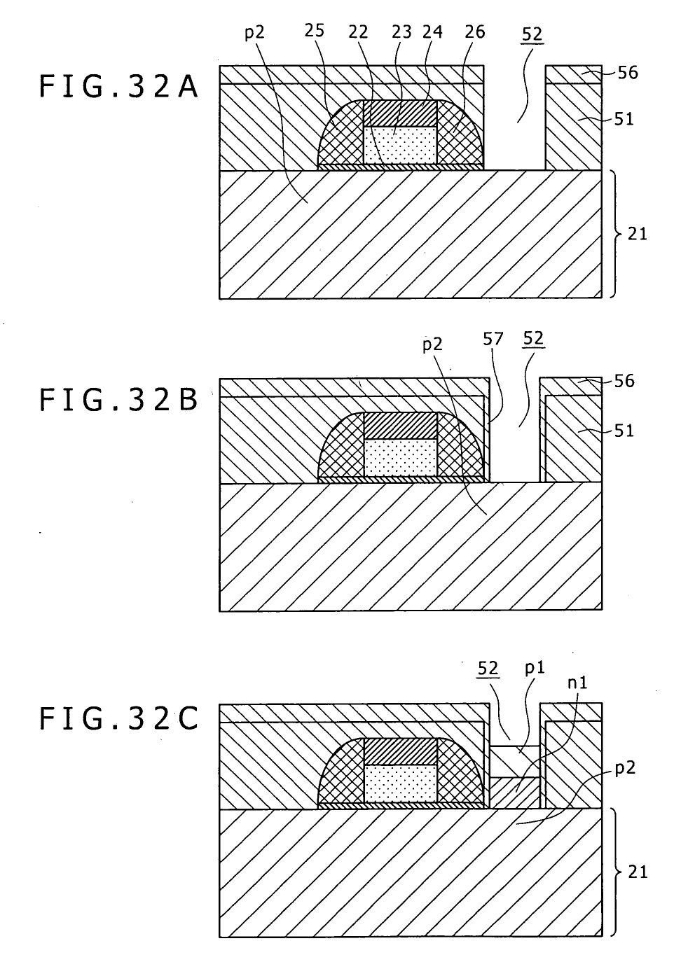

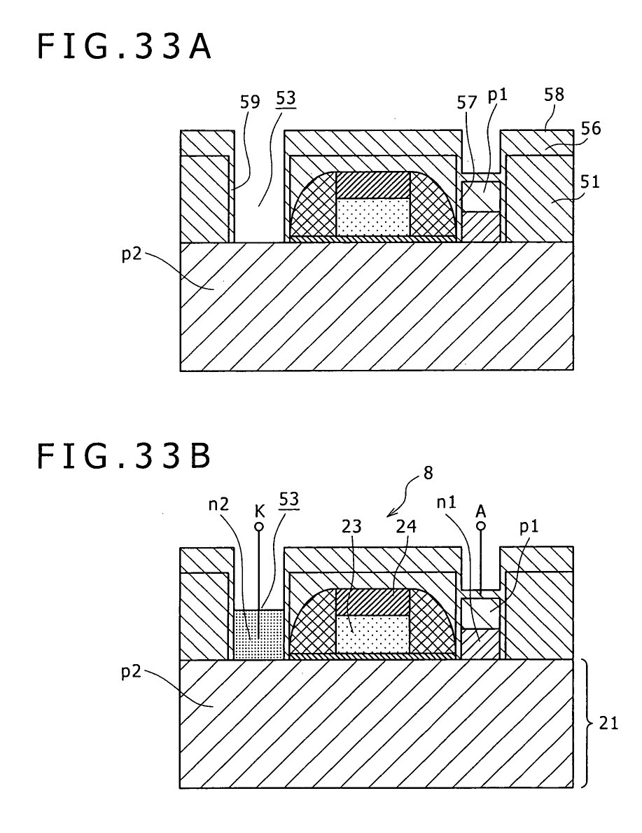

In the next place, a modified example of the fourth example of one embodiment of the method of manufacturing a semiconductor device in the present invention will be described, referring to manufacturing step sectional diagrams shown in FIGS. 32A to 33B. This modified example is an example in which the epitaxial growth in the fourth example of the manufacturing method above is made in the inside of a hole.

As shown in FIG. 32A, referring to the description made referring to FIGS. 24A to 24C, a silicon substrate, for example, is used as a semiconductor substrate 21, element isolating regions (not shown) for isolating element forming regions from each other are formed in the semiconductor substrate 21, and an upper part of each element forming regions in the semiconductor substrate 21 is formed into a region of a first conduction type (p-type). This p-type region will be a second p-type region p2 of a thyristor. In one example of a set of ion implantation conditions, boron (B) which is a p-type dopant is adopted as a dopant, and the dose is so set as to give a dopant concentration of 5×10¹⁸ cm⁻³, for example. The dopant concentration is desirably in the range of about 1×10¹⁸ to 1×10¹⁹ cm⁻³, and, basically, should be lower than the dopant concentration in a first n-type region of a second conduction type (n-type) which will be described later. As the p-type dopant, p-type impurities such as indium (In) may be used, other than boron (B).

Next, a gate insulating film 22 is formed over the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can also be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Subsequently, a gate electrode 23 is formed over the gate insulating film 22 on the upper side of the region to be the second p-type region p2. The gate electrode 23 is usually formed of polycrystalline silicon. Alternatively, a metal gate electrode may be used. Further, the gate electrode 23 may also be formed of silicon-germanium (SiGe) or the like.

The gate electrode 23 may be formed, for example, by forming a gate electrode forming film over the gate insulating film 22, forming an etching mask by ordinary resist application and lithography techniques, and etching the gate electrode forming film by an etching technique using the etching mask. As the etching technique, an ordinary dry etching technique can be used. Alternatively, wet etching may be used. Further, a silicon oxide (SiO₂) film, a silicon nitride (Si₃N₄) film or the like may be formed as a hard mask 24 over the gate electrode forming film.

Next, side walls 25 and 26 are formed on side walls of the gate electrode 23. The side walls 25, 26 can be formed, for example, by forming a side wall forming film so as to cover the gate electrode 23, and etching back the side wall forming film. The side walls 25, 26 may each be formed of silicon oxide (SiO₂), silicon nitride (Si₃N₄), or a laminate film of these materials.

Next, a first insulating film 51 is formed to cover the gate electrode 23, the hard mask 24, the side walls 25, 26 and the like. The first insulating film 51 is formed, for example, by depositing silicon oxide formed by a high-density plasma CVD method (HDP-SiO₂) in a thickness of 500 nm. Further, a second insulating film 56 is formed. The second insulating film 56 is formed, for example, by depositing a silicon nitride film in a thickness of 50 nm.

Subsequently, an etching mask (not shown) opened on one side of the gate electrode 23, specifically, opened over the second p-type region p2 in the area where to form a first n-type region, is formed by ordinary resist application and lithography techniques. Followingly, the second insulating film 56 and the first insulating film 51 on one side of the gate electrode 23 are provided with an opening part 52 by etching using the etching mask.

Next, as shown in FIG. 32B, a third insulating film 57 is formed so as to cover the second insulating film 56 and the inside surfaces of the opening part 52. The third insulating film 57 is formed, for example, by depositing a silicon nitride film in a thickness of 20 nm. Thereafter, the third insulating film 57 is etched, to expose the second p-type region p2 at a bottom portion of the opening part 52. By this it is possible to expose the surface of the silicon (Si) substrate only in the area of selective epitaxial growth. In the etching step, the third insulating film 57 over the surface of the second insulating film 56 is also removed. While the second insulating film 56 and the third insulating film 57 each composed of a silicon nitride film were formed as an example here, these insulating films are for securing selectivity at the time of epitaxial growth and, therefore, other kinds of insulating films can also be used inasmuch as selectivity can be thereby maintained. In addition, the second insulating film 56 and the third insulating film 57 may be omitted if the selective growth in epitaxial growth can be achieved by the presence of the first insulating film 51 alone.

Subsequently, as shown in FIG. 32C, a first n-type region n1 of the second conduction type (n-type) is formed in the inside of the opening part 52 over the second p-type region p2. In this case, cleaning of the surface of the silicon (Si) substrate by use of a chemical liquid such as hydrofluoric acid (HF) and hydrogen (H₂) gas may be conducted, as required. The first n-type region n1 is formed, for example, by selective epitaxial growth, with a phosphorus (P) concentration in film set to 1.5×10²⁰ cm⁻³. In one example of a set of selective epitaxial growth conditions, a diborane (B₂H₆) gas was used as a dopant gas, the substrate temperature at the time of film formation was set to, for example, 750° C., and the quantities of the raw material gases supplied, the pressure of the film-forming atmosphere, etc. were so controlled as to obtain a film thickness of 100 nm, for example. The dopant (arsenic) concentration is desirably in the range of about 1×10¹⁸ to 1×10²¹ cm⁻³. In addition, the film thickness is desirably in the range of about 50 to 300 nm. Besides, an arsine (AsH₃) gas may be used as the dopant gas; further, phosphine (PH₃), organic sources containing an n-type impurity, and the like may be used as the dopant gas.

Furthermore, in succession to the just-mentioned epitaxial growth, a first p-type region p1 of the first conduction type (p-type) is formed over the first n-type region n1. The first p-type region p1 is formed, for example, by selective epitaxial growth, with a boron (B) concentration in film set to, for example, 1×10²⁰ cm⁻³. In one example of a set of selective epitaxial growth conditions, a diborane (B₂H₆) gas was used as a raw material gas, the substrate temperature at the time of film formation was set to, for example, 750° C., and the quantities of the raw material gases supplied, the pressure of the film forming atmosphere, etc. were so controlled as to give a film thickness of 200 nm, for example. The dopant (boron) concentration is desirably in the range of about 1×10¹⁸ to 1×10²¹ cm⁻³. Besides, the film thickness is desirably in the range of about 50 to 300 nm, but it suffices for the thickness to be in such a range that the first p-type region p1 can function as an anode.

Next, as shown in FIG. 33A, a fourth insulating film 58 is formed so as to cover the second insulating film 56 and the first p-type region p1. The fourth insulating film 58 is formed, for example, by depositing a silicon nitride film in a thickness of 20 nm. Then, an etching mask (not shown) opened on the other side (the left side in the figure) of the gate electrode 23, specifically, opened over the second p-type region p2 in the area where to form a second n-type region, is formed by ordinary resist application and lithography techniques. Subsequently, the insulating films ranging from the fourth insulating film 58 to the first insulating film 51 on the other side of the gate electrode 23 are provided with an opening part 53 by an etching technique using the etching mask. Thereafter, the etching mask is removed. Next, a fifth insulating film 59 is formed over the whole area inclusive of the inside surfaces of the opening part 53. The fifth insulating film 59 is formed, for example, by depositing a silicon nitride film in a thickness of 20 nm. Thereafter, the fifth insulating film 59 is etched, to expose the second p-type region p2 at a bottom portion of the opening part 53. By this it is possible to expose the surface of the silicon (Si) substrate only in the area of selective epitaxial growth. In this etching step, the fifth insulating film 59 over the fourth insulating film 58 is also removed. While the fourth insulating film 58 and the fifth insulating film 59 each composed of the silicon nitride film were formed as an example here, these insulating films are for securing selectivity at the time of epitaxial growth and, therefore, other kinds of insulating films and other film thicknesses may also be adopted insofar as the selectivity can be thereby achieved. In addition, the fourth insulating film 58 and the fifth insulating film 59 may be omitted together with the second insulating film 56 and the third insulating film 57 if selectivity in epitaxial growth can be secured by the presence of the first insulating film 51 alone.

Subsequently, as shown in FIG. 33B, a second n-type region n2 of the second conduction type (n-type) is formed in the inside of the opening part 53 over the second p-type region p2. The second n-type region n2 is formed, for example, by selective epitaxial growth, with an arsenic (As) concentration in film set to 1×10²⁰ cm⁻³. In one example of a set of selective epitaxial growth conditions, a diborane (B₂H₆) gas was used as a dopant gas, the substrate temperature at the time of film formation was set to, for example, 750° C., and the quantities of the raw material gases supplied, the pressure of the film-forming atmosphere, etc. were so controlled as to obtain a film thickness of 200 nm, for example. The dopant (arsenic) concentration is desirably in the range of about 1×10¹⁸ to 1×10²¹ cm⁻³. In addition, the film thickness is desirably in the range of about 50 to 300 nm, but it suffices for the thickness to be in such a range that the second n-type region n2 can function as a cathode. Besides, an arsine (AsH₃) gas may be used as the dopant gas; further, phosphine (PH₃), organic sources containing an n-type impurity, and the like may be used as the dopant gas.

In addition, while the first n-type region n1, the first p-type region p1 and the second n-type region n2 were formed in this order in the just-described example, they may be formed in the order of the second n-type region n2, the first n-type region n1 and the first p-type region p1. Besides, in this case, cleaning of the surface of the silicon (Si) substrate by use of a chemical liquid such as hydrofluoric acid (HF) or hydrogen (H₂) gas or the like may be conducted, as required. Further, after the first p-type region p1 or the second n-type region n2 is formed, either one or both of the regions may be subjected to activating annealing, if necessary. As the activating annealing, for example, spike annealing at 1000° C. for 1 msec or less is conducted. It suffices for the annealing conditions in this case to be selected within such ranges that activation of the dopant can be achieved.

Next, an anode A connected to the first p-type region p1 and a cathode K connected to the second n-type region n2 are formed, by an ordinary electrode forming technique. In this instance, for exposing the first p-type region p1, the fourth insulating film 58 and the fifth insulating film 59 over the regions are removed. In addition, before forming a layer insulating film (not shown), the hard mask 24 and the insulating films over the gate electrode 23 may be removed and a silicide (titanium silicide, cobalt silicide, nickel silicide or the like) may be formed by siliciding step over the first p-type region p1, the second n-type region n2 and the gate electrode 23 thus exposed. Thereafter, a wiring step is conducted in the same manner as in the ordinary CMOS process.

In the method of manufacturing the semiconductor device 8 as just-described (the modified example of the fourth example of the manufacturing method), the first n-type region n1 and the first p-type region p1 are sequentially stackedly formed over a part of the second p-type region p2 and, further, the second n-type region n2 is stackedly formed over the second p-type region p2, so that a reduction in device size can be achieved. Moreover, since the first n-type region n1 and the first p-type region p1 are self-alignedly formed in the opening part 52 and, further, the second n-type region n2 is self-alignedly formed in the opening part 53, a further reduction in cell area can be realized. In addition, since the first p-type region p1 and the first n-type region n1 are formed above the semiconductor substrate 21, it is possible to secure a margin in the thickness direction of the first n-type region n1 between the first p-type region p1 and the second p-type region p2, and punch-through resistance is enhanced advantageously. Further, the process margins are increased, and it is possible to secure wider windows of device characteristics. As a result, improvements in characteristics can be attained, and this manufacturing method can be applied to the manufacture of the devices of the coming generations.

Now, a fifth example of one embodiment of the method of manufacturing a semiconductor device in the present invention will be described below. This example is an example of the method of manufacturing the semiconductor device 9 shown in FIG. 9.

The method of manufacturing the semiconductor device 9 described referring to FIG. 9 above is a method in which, in the manufacturing method described above referring to FIGS. 22A to 23C, before the formation of the first p-type region p1 in the step described referring to FIG. 23C, a diffusion preventive layer 31 comparable in dopant concentration comparable to the first n-type region n1 is formed by forming an n-type epitaxial layer, and thereafter the first p-type region p1 is formed over the diffusion preventive layer 31.

In the method of manufacturing the semiconductor device 9 as just-described, the diffusion preventive layer 31 comparable to the first n-type region n1 in dopant concentration is formed before the formation of the first p-type region p1, whereby the impurity in the first p-type region p1 can be restrained from diffusing into the semiconductor substrate 21 (the first n-type region n1). Incidentally, the same component parts as those shown in FIG. 9 have been denoted here by the same symbols as used in FIG. 9.

In the next place, a modified example of the fifth example of one embodiment of the method of manufacturing a semiconductor device in the present invention will be described below. This modified example is an example in which the epitaxial growth in the fifth example of the manufacturing method is made in the inside of an opening part (e.g., a hole).

The method of manufacturing the semiconductor device 10 described referring to FIG. 10 above is a method in which, after the first insulating film 51 is formed to have a height above the height of the gate electrode 23, in the step of FIG. 23B illustrating the method of manufacturing the semiconductor device 1, an opening part 52 is formed in the first insulating film 51 over the first n-type region n1. Then, a diffusion preventive layer 31 comparable in dopant concentration to the first n-type region n1 is formed by forming, for example, an n-type epitaxial layer in the inside of the opening part 52. Thereafter, a p-type region is epitaxially grown over the diffusion preventive layer 31, to form the first p-type region p1. In this manner, the semiconductor device 10 described referring to FIG. 10 above can be formed.

In the method of manufacturing the semiconductor device 10 as just-described, the diffusion preventive layer 31 comparable to the first n-type region n1 in dopant concentration is formed before forming the first p-type region p1, whereby the impurity in the first p-type region p1 can be restrained from diffusing into the semiconductor substrate 21 (the first n-type region n1). Incidentally, the same component parts as those shown in FIG. 10 above have been denoted here by the same symbols as used in FIG. 10.

Now, a sixth example of one embodiment of the method of manufacturing a semiconductor device in the present invention will be described below. This example is an example of the method of manufacturing the semiconductor device 11 shown in FIG. 11.

The method of manufacturing the semiconductor device 11 described referring to FIG. 11 above is a method in which, in the manufacturing method described above referring to FIGS. 24A to 25C, before the formation of the second n-type region n2 in the step described referring to FIG. 25B above, a diffusion preventive layer 32 comparable in dopant concentration to the second p-type region p2 is formed by forming, for example, a p-type epitaxial layer, and thereafter the second n-type region n2 is formed.

In the method of manufacturing the semiconductor device 11 as just-described, the diffusion preventive layer 32 comparable to the second p-type region p2 in dopant concentration is formed by forming the p-type epitaxial layer before the formation of the second n-type region n2, whereby the impurity in the second n-type region n2 can be restrained from diffusing into the semiconductor substrate 21 (the second p-type region p2). Incidentally, the same component parts as those shown in FIG. 11 above have been denoted here by the same symbols used in FIG. 11.

In the next place, a modified example of the sixth example of one embodiment of the method of manufacturing a semiconductor device in the present invention will be described below. This modified example is an example in which the epitaxial growth in the sixth example of the manufacturing method is made in the inside of an opening part (e.g., a hole).

The method of manufacturing the semiconductor device 12 described referring to FIG. 12 above is a method in which, in the manufacturing method described above referring to FIGS. 26A to 27C, before the formation of the second n-type region n2 in the step of FIG. 27C, a diffusion preventive layer 32 comparable in dopant concentration to the second p-type region p2 is formed by forming a p-type epitaxial layer, for example. Thereafter, an n-type region is epitaxially grown over the diffusion preventive layer 32, to form the second n-type region n2 over the diffusion preventive layer 32. In this manner, the semiconductor device 12 described referring to FIG. 12 above can be manufactured.

In the method of manufacturing the semiconductor device 12 as just-described, the diffusion preventive layer 32 comparable to the second p-type region p2 in dopant concentration is formed by forming the p-type epitaxial layer before the formation of the second n-type region n2, whereby the impurity in the second n-type region n2 can be restrained from diffusing into the semiconductor substrate 21 (the second p-type region p2). Incidentally, the same component parts as those shown in FIG. 12 above have been denoted here by the same symbols as used in FIG. 12.

Now, a seventh example of one embodiment of the method of manufacturing a semiconductor device in the present invention will be described below. This example is an example of the method of manufacturing the semiconductor device 13 shown in FIG. 13.

The method of manufacturing the semiconductor device 13 described referring to FIG. 13 above is a method in which, in the manufacturing method described above referring to FIGS. 24A to 25C, before forming the first p-type region, in the step described above referring to FIG. 24C, a diffusion preventive layer 31 comparable in dopant concentration to the first n-type region n1 is formed by forming, for example, an n-type epitaxial layer, and then the first p-type region p1 is formed. Further, before forming the second n-type region n2, in the step described above referring to FIG. 25B, a diffusion preventive layer 32 comparable in dopant concentration to the second p-type region p2 is formed by forming, for example, a p-type epitaxial layer, and thereafter the second n-type region n2 is formed over the diffusion preventive layer 32. In this manner, the semiconductor device 13 described referring to FIG. 13 above can be formed.

In the method of manufacturing the semiconductor device 13 as just-described, the diffusion preventive layer 31 comparable to the first n-type region n1 in dopant concentration is formed before the formation of the first p-type region p1, whereby the impurity in the first p-type region p1 can be restrained from diffusing into the semiconductor substrate 21 (the first n-type region n1). In addition, the diffusion preventive layer 32 comparable to the second p-type region p2 in dopant concentration is formed before the formation of the second n-type region n2, whereby the impurity in the second n-type region n2 can be restrained from diffusing into the semiconductor substrate 21 (the second p-type region p2). Incidentally, the same component parts as those shown in FIG. 13 above have been denoted here by the same symbols as used in FIG. 13.

In the next place, a modified example of the seventh example of one embodiment of the method of manufacturing a semiconductor device in the present invention will be described below. This modified example is an example in which the epitaxial growth in the seventh example of the manufacturing method is made in the inside of an opening part (e.g., a hole).

The method of manufacturing the semiconductor device 14 described referring to FIG. 14 above is a method in which, in the manufacturing method described above referring to FIGS. 26A to 27C, before forming the first p-type region p1, in the step described referring to FIG. 27A above, a diffusion preventive layer 31 comparable in dopant concentration to the first n-type region n1 is formed by forming, for example, an n-type epitaxial layer, and thereafter the first p-type region p1 is formed over the diffusion preventive layer 31. Further, before forming the second n-type region n2, in the step described referring to FIG. 27C above, a diffusion preventive layer 32 comparable in dopant concentration to the second p-type region p2 is formed by forming, for example, a p-type epitaxial layer, and thereafter the second n-type region n2 is formed over the diffusion preventive layer 32. In this manner, the semiconductor device 14 described referring to FIG. 14 above can be manufactured.

In the method of manufacturing the semiconductor device 14 as just-described, the diffusion preventive layer 31 comparable to the first n-type region in dopant concentration is formed before the formation of the first p-type region p1, whereby the impurity in the first p-type region p1 can be restrained from diffusing into the semiconductor substrate 21 (the first n-type region n1). In addition, the diffusion preventive layer 32 comparable to the second p-type region p2 in dopant concentration is formed before the formation of the second n-type region n2, whereby the impurity in the second n-type region n2 can be restrained from diffusing into the semiconductor substrate 21 (the second p-type region p2). Incidentally, the same component parts as those shown in FIG. 14 above have been denoted here by the same symbols as used in FIG. 14.

Now, an eighth example of one embodiment of the method of manufacturing a semiconductor device in the present invention will be described below. This example is an example of the method of manufacturing the semiconductor device 15 shown in FIG. 15 above.

The method of manufacturing the semiconductor device 15 described referring to FIG. 15 above is a method in which, in the manufacturing method described referring to FIGS. 22A to 23C, before forming the first p-type region p1, in the step described referring to FIG. 23C, a non-doped layer or a second conduction type (n-type) low-concentration region lower than the first n-type region n1 in dopant concentration or a first conduction type (p-type) low-concentration region lower than the first p-type region p1 in dopant concentration is formed as the low-concentration region 33 described referring to FIG. 15 above, and thereafter the first p-type region p1 is formed over the low-concentration region 33. In this manner, the semiconductor device 15 described referring to FIG. 15 can be manufactured.

In the method of manufacturing the semiconductor device 15 as just-described, the low-concentration region 33 is formed before the formation of the first p-type region, whereby an electric field is moderated, an enhanced withstand voltage can be realized, and an enhanced retention of the thyristor itself can be expected. Incidentally, the same component parts as those shown in FIG. 15 have been denoted here by the same symbols as used in FIG. 15.

In the next place, a modified example of the eighth example of one embodiment of the method of manufacturing a semiconductor device in the present invention will be described below. This modified example is an example in which the epitaxial growth in the eighth example of the manufacturing method is made in the inside of an opening part (e.g., a hole).

The method of manufacturing the semiconductor device 16 described referring to FIG. 16 above is a method in which, after forming the first insulating film 51 to be higher than the gate electrode 23, in the step of FIG. 23B illustrating the method of manufacturing the semiconductor device 1, an opening part 52 is formed in the first insulating film 51 over the first n-type region n1; thereafter, a non-doped layer or a second conduction type (n-type) low-concentration region lower than the first n-type region n1 in dopant concentration or a first conduction type (p-type) low-concentration region lower than the first p-type region in dopant concentration is formed in the opening part 52 by selective epitaxial growth, as the low-concentration region 33 described referring to FIG. 16 above. Thereafter, the first p-type region is formed over the low-concentration region 33. In this manner, the semiconductor device 16 described referring to FIG. 16 can be manufactured.

In the method of manufacturing the semiconductor device 16 as just-described, the low-concentration region 33 is formed before the formation of the first p-type region p1, whereby an electric field is moderated, an enhanced withstand voltage can be attained, and an enhanced retention of the thyristor itself can be expected. Incidentally, the same component parts as those shown in FIG. 16 have been denoted here by the same symbols as used in FIG. 16.

Now, a ninth example of one embodiment of the method of manufacturing a semiconductor device in the present invention will be described below. This example is an example of the method of manufacturing the semiconductor device 17 shown in FIG. 17 above.

The method of manufacturing the semiconductor device 17 described referring to FIG. 17 above is a method in which, in the manufacturing method described above referring to FIGS. 24A to 25C, before forming the second n-type region n2, in the step described referring to FIG. 25B, a non-doped layer or a second conduction type (n-type) low-concentration region lower than the first n-type region n1 in dopant concentration or a first conduction type (p-type) low-concentration region lower than the first p-type region p1 in dopant concentration is formed as the low-concentration region 34. Thereafter, the second n-type region n2 is formed over the low-concentration region 34. In this manner, the semiconductor device 17 described referring to FIG. 17 above can be manufactured.

In the method of manufacturing the semiconductor device 17 as just-described, the low-concentration region 34 is formed before the formation of the second n-type region n2, whereby an electric field is moderated, an enhanced withstand voltage can be attained, and an enhanced retention of the thyristor itself can be expected. Incidentally, the same component parts as those shown in FIG. 17 have been denoted here by the same symbols as used in FIG. 17.

In the next place, a modified example of the ninth example of one embodiment of the method of manufacturing a semiconductor device in the present invention will be described below. This modified example is an example in which the epitaxial growth in the ninth example of the manufacturing method is made in the inside of an opening part (e.g., a hole).

The method of manufacturing the semiconductor device 18 described referring to FIG. 18 above is a method in which, in the manufacturing method described referring to FIGS. 26A to 27C above, before forming the second n-type region, in the step of FIG. 27C, a non-doped layer or a second conduction type (n-type) low-concentration region lower than the first n-type region n1 in dopant concentration or a first conduction type (p-type) low-concentration region lower than the first p-type region p1 in dopant concentration is formed as the low-concentration region 34 by selective epitaxial growth. Thereafter, an n-type region is epitaxially grown over the low-concentration region 34, to form the second n-type region n2. In this manner, the semiconductor device 18 described referring to FIG. 18 can be manufactured.

In the method of manufacturing the semiconductor device 18 as just-described, the low-concentration region 34 is formed before the formation of the second n-type region, whereby an electric field is moderated, an enhanced withstand voltage can be attained, and an enhanced retention of the thyristor itself can be expected. Incidentally, the same component parts as those shown in FIG. 18 have been denoted here by the same symbols as used in FIG. 18.

According to the semiconductor devices and the manufacturing methods in the above examples, the area for forming the first p-type region p1 can be reduced and, therefore, the element area can be advantageously reduced by, for example, 30% or more, as compared with a semiconductor device in which the thyristor structure is formed in the so-called horizontal form according to the related art.

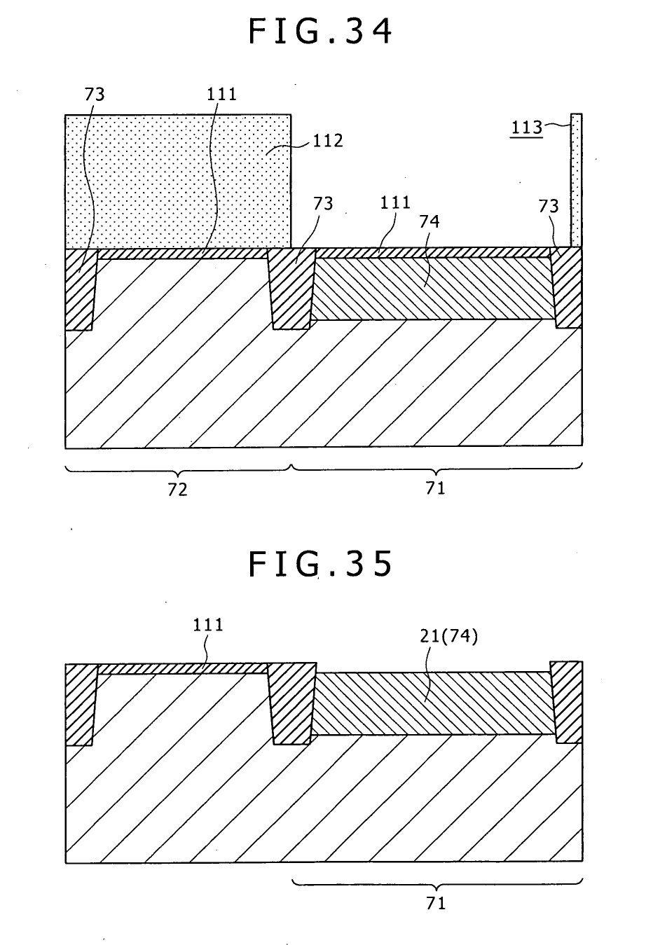

Now, a tenth example of one embodiment of the method of manufacturing a semiconductor device in the present invention will be described below, referring to manufacturing step diagrams shown in FIGS. 34 to 36. This example is an example of the method of manufacturing the semiconductor device 19 shown in FIG. 19.

As shown in FIG. 34, element isolating regions 73 for electrically isolating thyristor forming regions 71 and selecting transistor forming regions 72 from each other are formed in a semiconductor substrate 21. The element isolating regions 73 were formed, for example, in the type of STI (Shallow Trench Isolation) by the existing technology. Subsequently, a second conduction type (n-type) well region 74 is formed in the thyristor forming region 71. The n-type well region 74 is formed, for example, by an ion implanting technique. Besides, the depth (junction depth) of the n-type well region 74 is preferably set at a position shallower than the depth of end portions in the depth direction of the element isolating regions 73. This facilitates element isolation of the n-type well regions 74.

Next, an insulating film 111 is formed on the surface of the semiconductor substrate 21. The insulating film 111 is formed of a material which will serve as a mask at the time of epitaxial growth in a later step, for example, a silicon nitride film or a silicon oxide film. Subsequently, a resist film 112 is formed over the insulating film 111, and then the resist film 112 over the thyristor region 71 is removed by a lithography technique, to form an opening part 113. Thereafter, using the resist film 112 as an etching mask, the insulating film 111 over the thyristor forming region 71 is removed.

As a result, as shown in FIG. 35, the insulating film 111 (see FIG. 34) over the thyristor forming region 71 is removed, and the surface of the semiconductor substrate 21 (the n-type well region 74) is exposed. Thereafter, the resist film 112 (see FIG. 34) is removed.

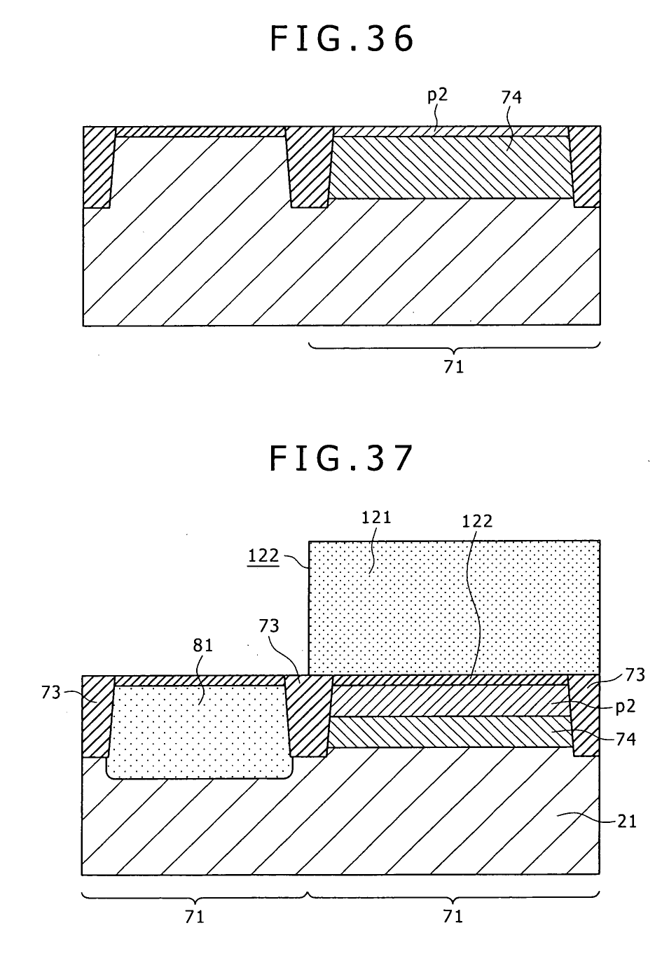

Using the insulating film 111 as a mask for epitaxial growth, an epitaxially grown layer is formed over the semiconductor substrate 21 in area of the thyristor forming region 71. In this epitaxial growth, for example, silicon is epitaxially grown while implanting boron (B) which is a p-type impurity, whereby the epitaxially grown layer is formed. As a result, as shown in FIG. 36, a second n-type region p2 composed of the epitaxially grown silicon layer to be a third region of a thyristor is formed over the n-type well region 74 in the area of the thyristor forming region 71.

Thereafter, though not shown, a gate insulating film is formed over the second p-type region p2, a gate electrode is formed, and side walls are formed on side wall parts of the gate electrode, as described above in the first to ninth examples of the manufacturing method in the present invention. Further, a first n-type region n1 and a first p-type region p1 are sequentially formed over the second p-type region p2 on one side of the gate electrode, with the side wall therebetween, and a second n-type region n2 is formed over the second p-type region p2 on the other side, with the side wall therebetween. In addition, together with the thyristor, an n-channel type field effect transistor, for example, is formed as a selecting transistor in the area of the selecting transistor forming region. In this case, the gate electrodes, the side walls and the like can be formed in common steps.

In the manufacturing method in the tenth example described just above, the second p-type region p2 of the thyristor is formed of the epitaxially grown silicon layer, so that it is easy to control the thyristor characteristics such as holding current, holding voltage, ON/OFF speed, etc. Therefore, it is easy to form a thyristor having desired characteristics. Further, since the second p-type region p2 is reduced in thickness, the volume thereof can be reduced, whereby the operating speed of the thyristor is enhanced. In addition, since the thyristor part is built upward from the semiconductor substrate 21, the element isolation width can be reduced, so that a reduction in cell size can be achieved.

Now, an eleventh example of one embodiment of the method of manufacturing a semiconductor device in the present invention will be described below, referring to FIGS. 37 to 39. This example is an example of the method of manufacturing the semiconductor device 19 20 shown in FIG. 20.

As shown in FIG. 37, element isolating regions 73 for electrically isolating thyristor forming regions 71 and selecting transistor forming regions 72 from each other are formed in a semiconductor substrate 21. The element isolating regions 73 were formed, for example, in the type of STI (Shallow Trench Isolation) by the existing technology. Subsequently, a second conduction type (n-type) well region 74 is formed in the thyristor forming region 71. The n-type well region 74 is formed, for example, by an ion implanting technique. Besides, the depth (junction depth) of the n-type well region 74 is preferably set at a position shallower than the depth of end portions in the depth direction of the element isolating regions 73. This facilitates element isolation of the n-type well regions 74. In addition, a p-type well region 81 is formed in the selecting transistor forming region 72.

Further, a second p-type region p2 to be a third region of a thyristor is formed over the n-type well region 74. The second p-type region p2 is formed, for example, by an ion implantation technique. Thereafter, an ion implanting mask used in the ion implantation is removed. Then, the surface of the semiconductor substrate 21 in the areas of the thyristor forming region 71 and the selecting transistor forming region 72 are exposed, and cleaned.

Next, a gate insulating film 22 is formed on the surface of the semiconductor substrate 21. The gate insulating film 22 is composed, for example, of a silicon oxide (SiO₂) film, in a thickness of about 1 to 10 nm. Incidentally, the material of the gate insulating film 22 is not limited to silicon oxide (SiO₂), and those gate insulating film materials which are investigated for application to ordinary CMOS can be used. Examples of the usable gate insulating film materials include not only silicon oxynitride (SiON) but also hafnium oxide (HfO₂), hafnium oxynitride (HfON), aluminum oxide (Al₂O₃), hafnium silicate (HfSiO), hafnium silicate nitride (HfSiON), and lanthanum oxide (La₂O₃).

Thereafter, a resist film 121 is formed over the gate insulating film 22, and then the resist film 121 over the selecting transistor forming region 72 is removed by a lithography technique, to form an opening part 122. Thereafter, using the resist film 121 as an etching mask, the gate insulating film 22 over the selecting transistor forming region 72 is removed.

As a result, as shown in FIG. 38, the insulating film 22 (see FIG. 37) over the selecting transistor forming region 72 is removed, and the surface of the semiconductor substrate 21 (the p-type well region 81) is exposed. Thereafter, the resist film 121 (see FIG. 37) is removed.

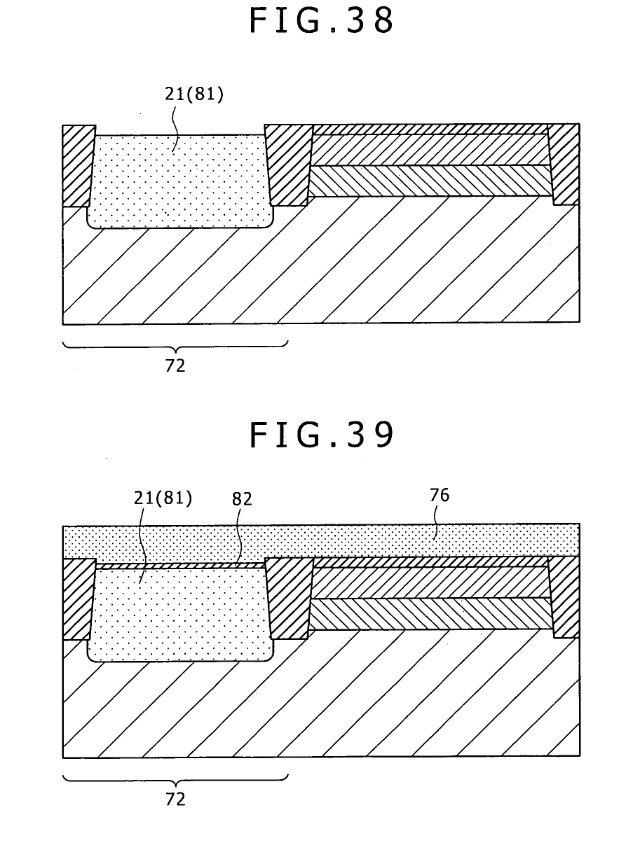

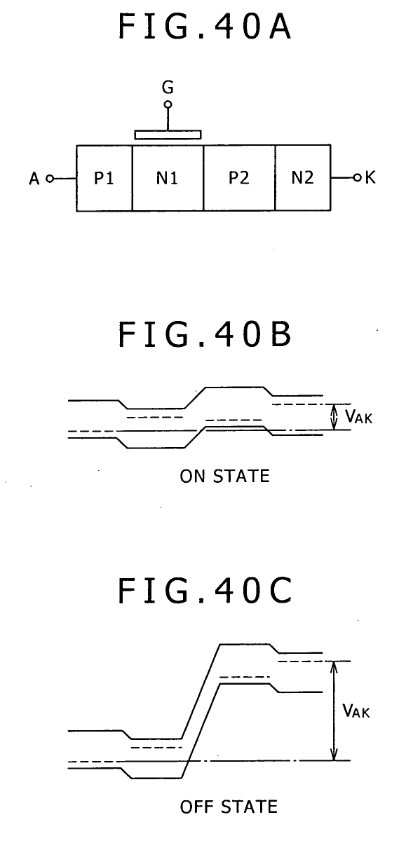

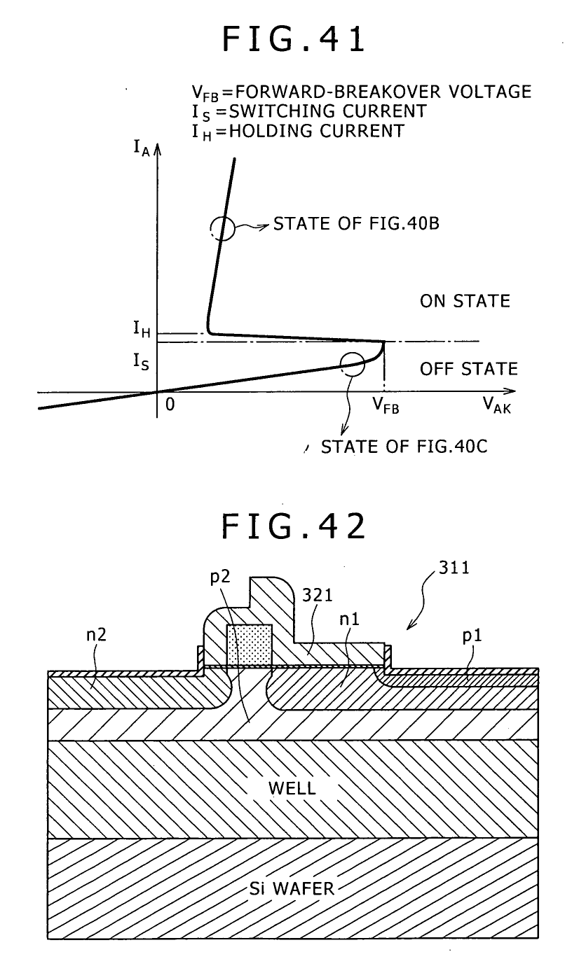

Next, as shown in FIG. 39, a gate insulating film 82 of a selecting transistor is formed in a desired film species and a desired thickness over the semiconductor substrate 21 (the p-type well region 81) in the area of the selecting transistor forming region 72. The gate insulating film 82 is composed, for example, of a silicon oxide (SiO2) film in a thickness of 2 to 3 nm. Further, a gate electrode material film 76 is formed over the whole surface. As the gate electrode material film 76, for example, a polysilicon film with a thickness of 150 to 200 nm is used.

Thereafter, though not shown, a gate electrode (not shown) composed of the gate electrode material film 76 is formed over the second p-type region p2, with the gate insulating film 22 therebetween, as described above in the first to ninth examples of the manufacturing method in the present invention. Though not shown, side walls are formed on side wall parts of the gate electrode. Further, a first n-type region n1 and a first p-type region p1 in this order from the lower side are formed over the second p-type region p2 on one side of the gate electrode, with the side wall therebetween, and a second n-type region n2 is formed over the second p-type region p2 on the other side of the gate electrode, with the side wall therebetween.

In addition, a gate electrode composed of the gate electrode material film 76 is formed in the area of the selecting transistor forming region 72, by an ordinary MOS transistor manufacturing method. Therefore, the gate electrode of the thyristor and the gate electrode of the selecting transistor can be formed simultaneously. Furthermore, extension regions are formed in the selecting transistor forming region on both sides of the gate electrode, and then side walls are formed on both sides of the gate electrode. The side walls can be formed simultaneously with the side walls of the thyristor. Thereafter, source/drain regions are formed in the p-type well region 81 to be the selecting transistor forming region on both sides of the gate electrode, with the side wall therebetween. Therefore, the p-type well region 81 on both sides of the gate electrode is provided with the source/drain regions, with the extension region therebetween.

In the above examples, the region formed by the epitaxial growth occurring upward from the semiconductor substrate 21 is composed of single crystal silicon. Besides, the epitaxial growth has been conducted while doping with an impurity such as to provide the desired conduction type. However, a method may be adopted in which all or part of the epitaxially grown layers are formed by non-doped epitaxial growth and, thereafter, doping with an impurity such as to provide the desired conduction type is carried out by an ion implantation technique or a solid state layer diffusion technique.

In addition, while the semiconductor substrate has been described as a semiconductor substrate in the above examples, the semiconductor substrate may be a semiconductor layer of an SOI (Silicon on insulator) substrate. In this case, it suffices for each region having been formed in the semiconductor substrate to be formed in the semiconductor layer of the SOI substrate. Besides, the other configurations having been formed over the semiconductor substrate can be formed over the semiconductor layer, in the same manner as above-described. Each region formed in the semiconductor layer can be formed by utilizing the whole region in the depth direction of the semiconductor layer. Incidentally, an under layer of the semiconductor layer is formed with a buried insulating layer (also referred to as BOX).

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device which has a thyristor including a first region of a first conduction type, a second region of a second conduction type opposite to said first conduction type, a third region of said first conduction type, and a fourth region of said second conduction type, in sequential junction, and has a gate electrode at said third region, wherein
said third region is formed in a semiconductor substrate,
said second region is formed in a part of said third region, and
said first region is formed on the upper side of said second region.

2. The semiconductor device as set forth in claim 1, wherein
said third region is formed in said semiconductor substrate, and
said fourth region is formed on the upper side of a part of said third region.

3. The semiconductor device as set forth in claim 1, wherein
said thyristor is formed in a thyristor forming region electrically isolated by an element isolating region formed in said semiconductor substrate,
said thyristor forming region includes a well region of said second conduction type formed in said semiconductor substrate, and
said well region is so formed that the junction position in the depth direction thereof is shallower than an end part in the depth direction of said element isolating region.

4. A semiconductor device which has a thyristor including a first region of a first conduction type, a second region of a second conduction type opposite to said first conduction type, a third region of said first conduction type, a fourth region of said second conduction type, in sequential junction, and has a gate electrode in said third region, wherein
said second region is formed on the upper side of a part of said third region, and
said first region is formed on the upper side of said second region.

5. The semiconductor device as set forth in claim 3, wherein
said third region is formed on the upper side of the semiconductor substrate.

6. The semiconductor device as set forth in claim 4, wherein
said second region is formed on the upper side of said third region on one side of said gate electrode,
said first region is formed on the upper side of said second region, and
said fourth region is formed on the upper side of said third region on the other side of said gate electrode.

7. The semiconductor device as set forth in claim 4, wherein
said third region is formed on the upper side of said semiconductor substrate.

8. The semiconductor device as set forth in claim 1, wherein
a diffusion inhibitive layer of said second conduction type is formed between said second region and said first region.

9. The semiconductor device as set forth in claim 2, wherein
a diffusion inhibitive layer of said first conduction type is formed between said third region and said fourth region.

10. The semiconductor device as set forth in claim 2, wherein
a diffusion inhibitive layer of said second conduction type is formed between said second region and said first region, and
a diffusion inhibitive layer of said first conduction type is formed between said third region and said fourth region.

11. The semiconductor device as set forth in claim 1, wherein
said first region is formed on the upper side of said second region, with a low-concentration region therebetween, and
said low-concentration region includes a non-doped layer, a second conduction type low-concentration region lower in dopant concentration than said second region, or a first conduction type low-concentration layer lower in dopant concentration than said first region.

12. The semiconductor device as set forth in claim 2, wherein
said fourth region is formed on the upper side of a part of said third region, with a low-concentration region therebetween, and
said low-concentration region includes a non-doped layer, a first conduction type low-concentration region lower in dopant concentration than said third region, or a second conduction type low-concentration region lower in dopant concentration than said fourth region.

13. A method of manufacturing a semiconductor device which has a thyristor including a first region of a first conduction type, a second region of a second conduction type opposite to said first conduction type, a third region of said first conduction type, and a fourth region of said second conduction type, in sequential junction, and has a gate electrode at said third region, said method comprising the steps of:
forming said third region in a semiconductor substrate;
forming said second region in a part of said third region; and
forming said first region on the upper side of said second region.

14. The method of manufacturing a semiconductor device as set forth in claim 13, comprising the steps of:
forming said third region in said semiconductor substrate; and
forming said fourth region on the upper side of a part of said third region.

15. A method of manufacturing a semiconductor device which has a thyristor including a first region of a first conduction type, a second region of a second conduction type opposite to said first conduction type, a third region of said first conduction type, and a fourth region of said second conduction type, in sequential junction, and has a gate electrode at said third region, said method comprising the steps of:
forming said second region on the upper side of a part of said third region; and
forming said first region on the upper side of said second region.

16. The method of manufacturing a semiconductor device as set forth in claim 15, comprising the steps of:
forming said second region on the upper side of said third region on one side of said gate electrode;
forming said first region on the upper side of said second region; and
forming said fourth region on the upper side of said third region on the other side of said gate electrode.

17. The method of manufacturing a semiconductor device as set forth in claim 13, comprising the step of:
forming a diffusion inhibitive layer of said second conduction type between said second region and said first region.

18. The method of manufacturing a semiconductor device as set forth in claim 14, comprising the step of:
forming a diffusion inhibitive layer of said first conduction type between said third region and said fourth region.

19. The method of manufacturing a semiconductor device as set forth in claim 14, comprising the steps of:
forming a diffusion inhibitive layer of said second conduction type between said second region and said first region; and
forming a diffusion inhibitive layer of said first conduction type between said third region and said fourth region.

20. The method of manufacturing a semiconductor device as set forth in claim 13, comprising the step of:
forming a low-concentration region on the upper side of said second region, said low-concentration region including a non-doped layer, a second conduction type low-concentration region lower in dopant concentration than said second region, or a first conduction type low-concentration region lower in dopant concentration than said first region;
before forming said first region on the upper side of said second region.

21. The method of manufacturing a semiconductor device as set forth in claim 14, comprising the step of:
forming a low-concentration region on the upper side of said third region, said low-concentration region including a non-doped layer, a first conduction type low-concentration region lower in dopant concentration than said third region, or a second conduction type low-concentration region lower than dopant concentration than said fourth region;
at the time of forming said fourth region on the upper side of a part of said third region.
